(19) United States
(12) Patent Application Publication
(10) Pub. No.: US 2025/0359172 A1
(43) Pub. Date: Nov. 20, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Feng-Ming CHANG, Hsinchu County (TW); Jui-Lin CHEN, Taipei City (TW); Ping-Wei WANG, Hsin-Chu (TW); Choh Fei YEAP, Hsinchu City (TW); Yu-Bey WU, Hsinchu City (TW)

(21) Appl. No.: 19/286,078

(22) Filed: Jul. 30, 2025

Related U.S. Application Data
(63) Continuation of application No. 18/405,318, filed on Jan. 5, 2024.
(60) Provisional application No. 63/589,738, filed on Oct. 12, 2023.
(60) Provisional application No. 63/613,486, filed on Dec. 21, 2023.

(51) Int. Cl. H10D 30/67; H10B 10/00; H10D 30/01; H10D 30/43; H10D 62/10; H10D 64/01; H10D 84/01; H10D 84/03; H10D 84/83

(52) U.S. Cl. CPC H10D 30/6735; H10B 10/12; H10D 30/014; H10D 30/43; H10D 30/6757; H10D 62/121; H10D 64/017; H10D 84/013; H10D 84/0135; H10D 84/0149; H10D 84/038; H10D 84/83

(57) ABSTRACT

A method for forming a semiconductor structure is provided. The method includes forming a first active region in which first semiconductor layers and second semiconductor layers are alternatingly stacked over a first lower fin element. In a plan view, the active region includes a first portion and a second portion narrower than the first portion. The method also includes removing the first semiconductor layers of the first active region. The second semiconductor layers of the first portion of the first active region form first nanostructures, and the second semiconductor layers of the second portion of the first active region form second nanostructures. The method also includes forming a first gate stack to surround the first nanostructures, and forming a second gate stack to surround the second nanostructures.

### PRIORITY CLAIM

This application is a Continuation of U.S. patent application Ser. No. 18/405,318 filed Jan. 5, 2024, which claims the benefit of U.S. Provisional Application No. 63/589,738, filed on Oct. 12, 2023, entitled “ACTIVE REGION DESIGN FOR MEMORY DEVICES,” and of U.S. Provisional Application No. 63/613,486, filed Dec. 21, 2023, entitled “SEMICONDUCTOR STRUCTURE AND METHOD FOR FORMING THE SAME” all of which are incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 illustrates a simplified diagram of a static random access memory (SRAM), in accordance with some embodiments of the disclosure.

FIG. 3A illustrates a single-port SRAM cell, in accordance with some embodiments of the disclosure.

FIG. 3B illustrates an alternative illustration of the SRAM cell of FIG. 3A, in accordance with some embodiments of the disclosure.

FIG. 4A illustrates a layout showing a group GP of the SRAM in FIG. 2, in accordance with some embodiments of the disclosure.

FIG. 4B illustrates the configuration of contact plugs on the layout of FIG. 4A, in accordance with some embodiments of the disclosure.

FIG. 4C illustrates an enlarged view of FIG. 4A to illustrate more details of jog structure of active regions, in accordance with some embodiments of the disclosure.

FIGS. 4D-1, 4D-2 and 4D-3 are cross-sectional views illustrating the formation of a semiconductor structure of an SRAM cell at one of the intermediate stages corresponding to line Y1-Y1, line Y2-Y2 and line X-X of FIG. 4A, in accordance with some embodiments of the disclosure.

FIGS. 4E-1, 4E-2 and 4E-3 are cross-sectional views illustrating the formation of a semiconductor structure of an SRAM cell at one of the intermediate stages corresponding to line Y1-Y1, line Y2-Y2 and line X-X of FIG. 4A, in accordance with some embodiments of the disclosure.

FIGS. 4F-1, 4F-2 and 4F-3 are cross-sectional views illustrating the formation of a semiconductor structure of an SRAM cell at one of the intermediate stages corresponding to line Y1-Y1, line Y2-Y2 and line X-X of FIG. 4A, in accordance with some embodiments of the disclosure.

FIGS. 4G-1, 4G-2 and 4G-3 are cross-sectional views illustrating the formation of a semiconductor structure of an SRAM cell at one of the intermediate stages corresponding to line Y1-Y1, line Y2-Y2 and line X-X of FIG. 4A, in accordance with some embodiments of the disclosure.

FIGS. 4D-4 and 4F-4 are plan views corresponding to plan A-A of FIGS. 4D-1 and 4F-1, in accordance with some embodiments of the disclosure.

FIG. 4F-5 is a plan view corresponding to plan B-B of FIG. 4F-1, in accordance with some embodiments of the disclosure.

FIGS. 5A, 5B and 5C are plan views illustrating active regions with smooth jogs, in accordance with some embodiments of the disclosure.

FIGS. 6A and 6B are plan views illustrating the formation of active regions with sharp jogs, in accordance with some embodiments of the disclosure.

FIGS. 6C-1 and 6C-2 are plan views of a semiconductor structure of SRAM cells corresponding to plan A-A and plan B-B, respectively, in accordance with some embodiments of the disclosure.

FIG. 7A illustrates a layout showing half of a group GP of the SRAM in FIG. 2, in accordance with some embodiments of the disclosure.

FIGS. 7B-1 and 7B-2 are plan views of a semiconductor structure of the SRAM cells of FIG. 7A corresponding to plan A-A and plan B-B of FIG. 4F-1, in accordance with some embodiments of the disclosure.

FIG. 8A illustrates a layout showing half of a group GP of the SRAM in FIG. 2, in accordance with some embodiments of the disclosure.

FIGS. 8B-1 and 8B-2 are plan views of a semiconductor structure of the SRAM cells of FIG. 8A corresponding to plan A-A and plan B-B of FIG. 4F-1, in accordance with some embodiments of the disclosure.

FIGS. 9A and 9B are plan views illustrating an active region with a smooth jog, in accordance with some embodiments of the disclosure.

FIG. 10A illustrates a layout showing a group GP of the SRAM in FIG. 2, in accordance with some embodiments of the disclosure.

FIG. 10B is a plan view of a semiconductor structure of the SRAM cells of FIG. 10A corresponding to plan B-B, in accordance with some embodiments of the disclosure.

FIG. 11A illustrates a layout showing a group GP of the SRAM in FIG. 2, in accordance with some embodiments of the disclosure.

FIG. 11B is a plan view of the semiconductor structure of the SRAM cells of FIG. 11A corresponding to plan B-B, in accordance with some embodiments of the disclosure.

FIG. 12A illustrates a layout showing a group GP of the SRAM in FIG. 2, in accordance with some embodiments of the disclosure.

FIG. 12B is a plan view of the semiconductor structure of the SRAM cells of FIG. 12A corresponding to plan B-B, in accordance with some embodiments of the disclosure.

FIG. 13A illustrates a layout showing a group GP of the SRAM in FIG. 2, in accordance with some embodiments of the disclosure.

FIGS. 13B-1 and 13B-2 are cross-sectional views of a semiconductor structure of an SRAM cell corresponding to line Y1-Y1 and line Y2-Y2 of FIG. 13A, in accordance with some embodiments of the disclosure.

FIG. 13B-3 is a plan view corresponding to plan B-B of FIG. 13B-1, in accordance with some embodiments of the disclosure.

FIG. 14A illustrates the configuration of backside contact plugs on the layout of FIG. 4A, in accordance with some embodiments of the disclosure.

FIGS. 14B-14E are cross-sectional views illustrating the formation of a semiconductor structure of an SRAM cell at various intermediate stages corresponding to line Y2-Y2 of FIG. 14A, in accordance with some embodiments of the disclosure.

FIG. 15A illustrates the configuration of backside contact plugs on the layout of FIG. 13, in accordance with some embodiments of the disclosure.

FIG. 15B is a cross-sectional view of a semiconductor structure of an SRAM cell corresponding to line Y2-Y2 of FIG. 15A, in accordance with some embodiments of the disclosure.

FIG. 16A illustrates a layout showing a group GP of the SRAM in FIG. 2, in accordance with some embodiments of the disclosure.

FIGS. 16B-1 and 16B-2 are cross-sectional views of a semiconductor structure of an SRAM cell corresponding to line Y1-Y1 and line Y2-Y2 of FIG. 16A, in accordance with some embodiments of the disclosure.

FIG. 16B-3 is a plan view corresponding to plan B-B of FIG. 16B-1, in accordance with some embodiments of the disclosure.

FIG. 17A illustrates a layout showing a group GP of the SRAM in FIG. 2, in accordance with some embodiments of the disclosure.

FIGS. 17B-1 and 17B-2 are cross-sectional views of a semiconductor structure of an SRAM cell corresponding to line Y1-Y1 and line Y2-Y2 of FIG. 17A, in accordance with some embodiments of the disclosure.

FIG. 17B-3 is a plan view corresponding to plan B-B of FIG. 17B-1, in accordance with some embodiments of the disclosure.

FIG. 18A illustrates the configuration of backside contact plugs on the layout of FIG. 17A, in accordance with some embodiments of the disclosure.

FIG. 18B is a cross-sectional view of a semiconductor structure of an SRAM cell corresponding to line Y2-Y2 of FIG. 18A, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As the feature sizes continue to decrease, SRAM devices have also begun to adopt nanostructure transistor (e.g., GAA FET) solutions to improve cell performance, e.g., cell current, operation voltage (e.g., Vmax, Vmin, etc.), SRAM margin (e.g., write margin and/or read margin) and/or operation speed. The aspect of the present disclosure is directed to forming a semiconductor structure of an SRAM device including nanostructure transistors. The active regions of the semiconductor structure may be formed with jog structure, and thus independent adjustment of the performances of the pull-down transistor (PD) and the pass-gate transistor (PG) formed on the active regions may be achieved. The channel width of the pull-down transistor may be greater than the channel width of the pass-gate transistor. As a result, the pull-down transistor may have a stronger performance than the pass-gate transistor. Therefore, the cell performance of the resulting SRAM cells may be improved, e.g., higher operation voltage (e.g., Vmax), higher cell current, broader read margin metric, and/or faster operation speed.

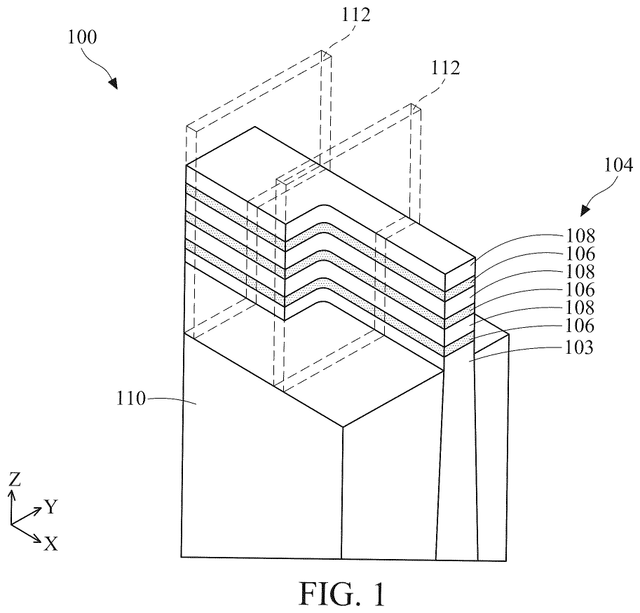

FIG. 1 is a perspective view of a semiconductor structure 100, in accordance with some embodiments of the disclosure. In some embodiments, the semiconductor structure 100 is used to form SRAM cells. The semiconductor structure 100 includes a fin structure 104 over a substrate, in accordance with some embodiments. Although one fin structure is illustrated in FIG. 1, the semiconductor structure 100 may include more than one fin structures 104.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104 includes a lower fin element 103 formed from a portion of the substrate and an upper fin element formed from an epitaxial stack of alternating first semiconductor layers 106 and second semiconductor layer 108, in accordance with some embodiments. An isolation structure 110 surrounds the lower fin element 103, in accordance with some embodiments. The second semiconductor layers 108 will form nanostructures (e.g., nanowires or nanosheets) and serve as the channels for the resulting nanostructure transistors, in accordance with some embodiments.

The fin structure 104 extends in X direction, in accordance with some embodiments. That is, the fin structure 104 has a longitudinal axis that is parallel with the X direction, in accordance with some embodiments. The X direction may also be referred to as the channel-extending direction. The current of the resulting semiconductor device (i.e., nanostructure transistor) flows in the X direction through the channel.

The fin structure 104 includes channel regions and source/drain regions, and the channel regions and the source/drain regions are arranged in the X direction in such a way that they alternate, in accordance with some embodiments. In this disclosure, the term “source/drain” refers to a source, a drain, or both. It should be noted that in the present disclosure, the source and drain are used interchangeably, and their structures are substantially the same. Gate structures 112 are formed with longitudinal axes parallel to the Y direction and extending across and/or surrounding the channel regions of the fin structure 104. The Y direction may also be referred to as the gate-extending direction.

In addition, as shown in FIG. 1, the fin structure 104 is a semiconductor strip with a jog structure, in accordance with some embodiments. As the term is used herein, “jog” refers to a strip extending in a horizontal direction, with a dent or protrusion on one or both sides of the strip. The fin structure 104 with a jog structure may include a wider portion and a narrower portion, so that the transistors formed the wider portion and the narrower portion of the fin structure 104 have different performances (e.g., different saturation currents (Idsat)), in accordance with some embodiments. Therefore, the cell of the resulting SRAM cells may be optimally enhanced, which will be described in detail later.

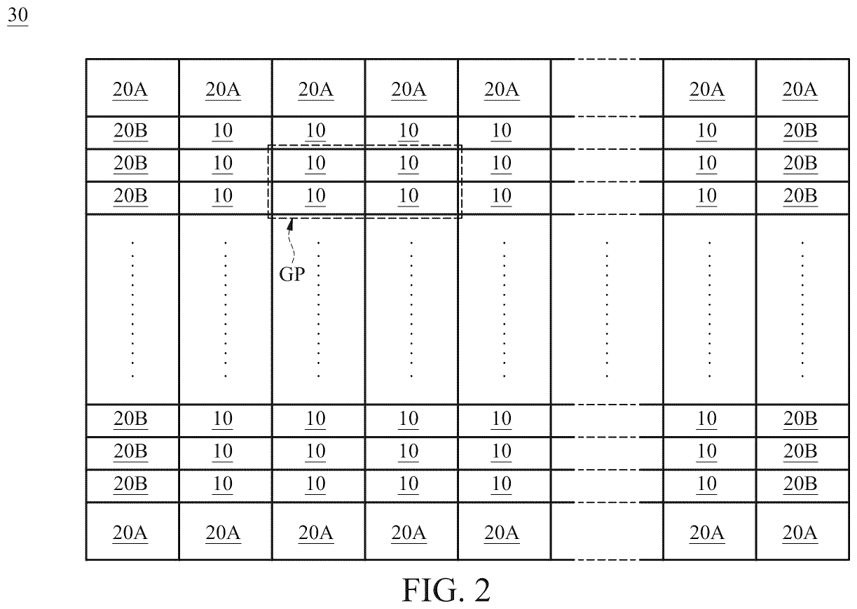

FIG. 2 illustrates a simplified diagram of an SRAM 30, in accordance with some embodiments of the disclosure. The SRAM 30 can be an independent device or be implemented in an IC (e.g. System-on-Chip (SOC)). The SRAM 30 includes a cell array formed by multiple SRAM cells (or called bit cells) 10, and the SRAM cells 10 are arranged in multiple rows and multiple columns in the cell array.

In the fabrication of SRAM cells, the cell array may be surrounded by multiple strap cells 20A and multiple edge cells 20B, and the strap cells 20A and the edge cells 20B are dummy cells for the cell array. In some embodiments, the strap cells 20A are arranged to surround the cell array horizontally, and the edge cells 20B are arranged to surround the cell array vertically. The shapes and sizes of the strap cells 20A and the edge cells 20B are determined according to actual application.

In some embodiments, the shapes and sizes of the strap cells 20A and the edge cells 20B are the same as the SRAM cells 10. In some embodiments, the shapes and sizes of the strap cells 20A, the edge cells 20B and the SRAM cells 10 are different. Moreover, in the SRAM 30, each SRAM cell 10 has the same rectangular shape/region, e.g., the widths and heights of the SRAM cells 10 are the same. The configurations of the SRAM cells 10 are described below.

In the cell array of the SRAM 30, although only one group GP is shown in FIG. 2, the SRAM cells 10 can be divided into multiple groups GP, and each of the groups GP includes four adjacent SRAM cells 10. The groups GP are described in detail below.

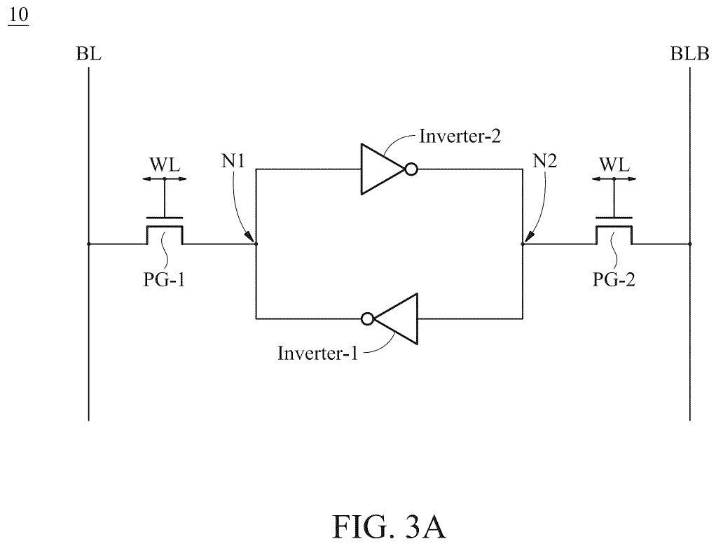

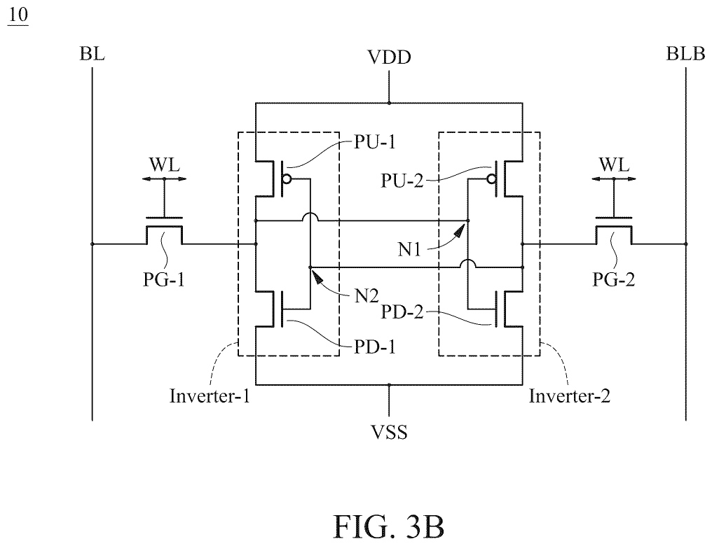

FIG. 3A illustrates a single-port SRAM cell 10, in accordance with some embodiments of the disclosure. The SRAM cell 10 includes a pair of cross-coupled inverters Inverter-1 and Inverter-2, and two pass-gate transistors PG-1 and PG-2. The inverters Inverter-1 and Inverter-2 are cross-coupled between the nodes N1 and N2, and form a latch.

The pass-gate transistor PG-1 is coupled between a bit line BL and the node N1, and the pass-gate transistor PG-2 is coupled between a complementary bit line BLB and the node N2, and the complementary bit line BLB is complementary to the bit line BL. The gates of the pass-gate transistors PG-1 and PG-2 are coupled to the same word-line WL. The pass-gate transistors PG-1 and PG-2 are NMOS transistors.

FIG. 3B illustrates an alternative illustration of the SRAM cell of FIG. 3A, in accordance with some embodiments of the disclosure. The inverter Inverter-1 in FIG. 3A includes a pull-up transistor PU-1 and a pull-down transistor PD-1, as shown in FIG. 3B. The pull-up transistor PU-1 is a PMOS transistor, and the pull-down transistor PD-1 is an NMOS transistor. The drain of the pull-up transistor PU-1 and the drain of the pull-down transistor PD-1 are coupled to the node N1 connecting the pass-gate transistor PG-1. The gates of the pull-up transistor PU-1 and the pull-down transistor PD-1 are coupled to the node N2 connecting the pass-gate transistor PG-2. Furthermore, the source of the pull-up transistor PU-1 is coupled to a power supply node VDD, and the source of the pull-down transistor PD-1 is coupled to a ground VSS.

Similarly, the inverter Inverter-2 in FIG. 3A includes a pull-up transistor PU-2 and a pull-down transistor PD-2, as shown in FIG. 3B. The pull-up transistor PU-2 is a PMOS transistor, and the pull-down transistor PD-2 is an NMOS transistor. The drains of the pull-up transistor PU-2 and the pull-down transistor PD-2 are coupled to the node N2 connecting the pass-gate transistor PG-2. The gates of the pull-up transistor PU-2 and the pull-down transistor PD-2 are coupled to the node N1 connecting the pass gate transistor PG-1. Furthermore, the source of the pull-up transistor PU-2 is coupled to the power supply node VDD, and the source of the pull-down transistor PD-2 is coupled to the ground VSS.

In some embodiments, the pass-gate transistors PG-1 and PG-2, the pull-up transistors PU-1 and PU-2, and the pull-down transistors PD-1 and PD-2 of the SRAM cell 10 are nanostructure transistors (such as gate-all-around transistors).

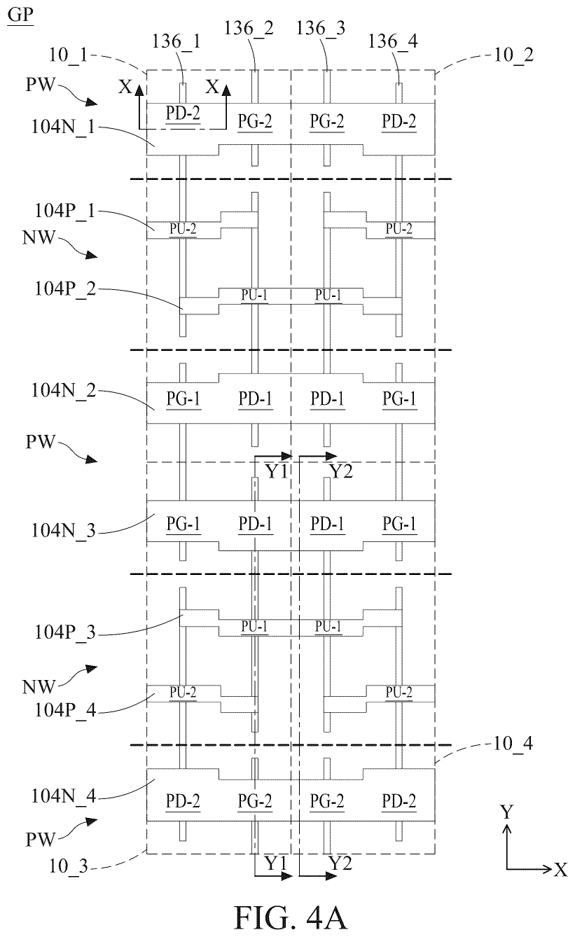

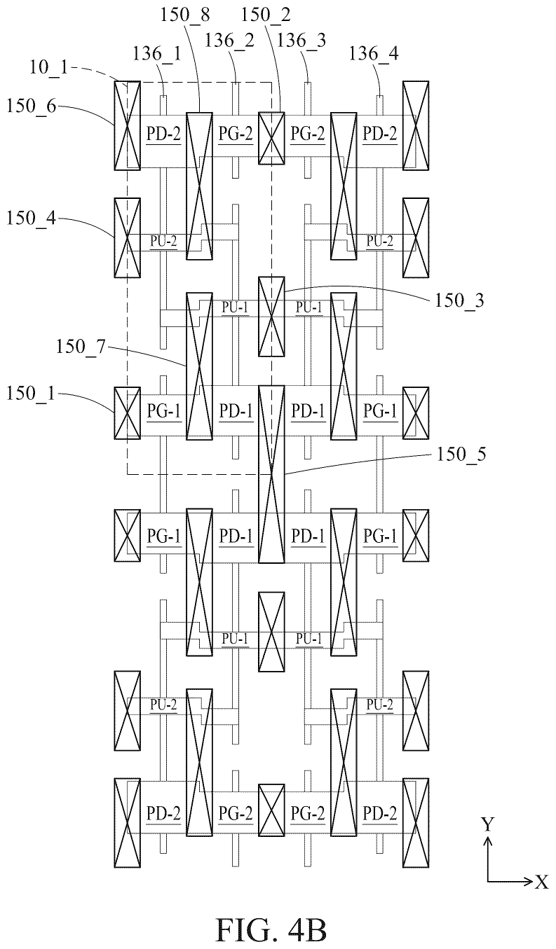

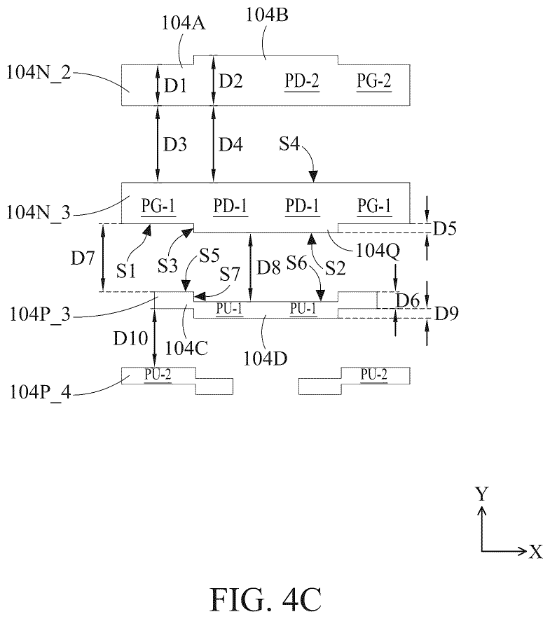

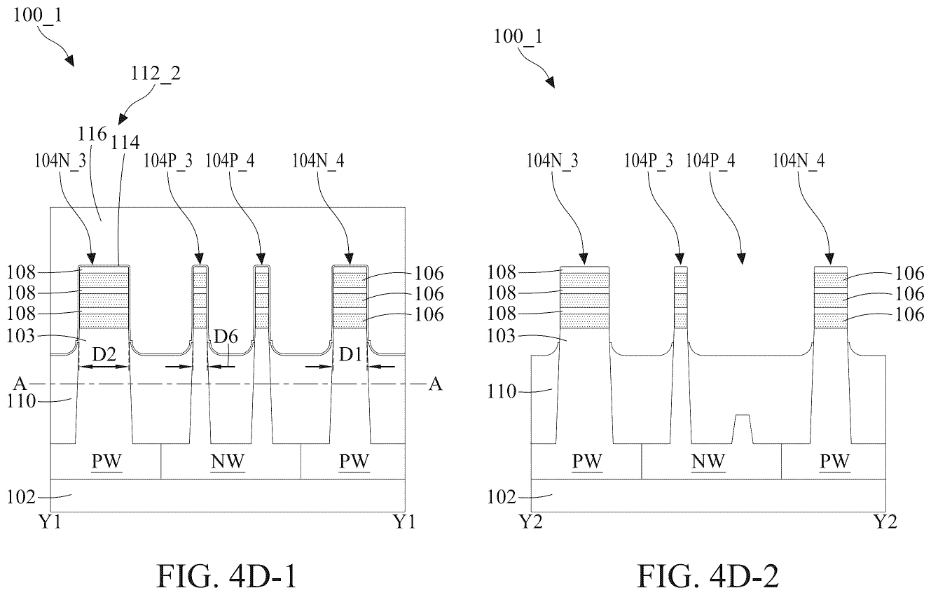

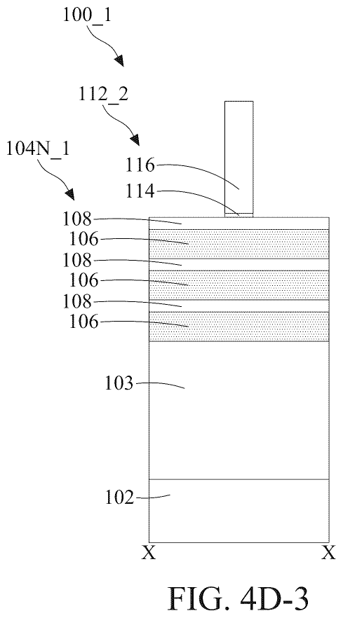

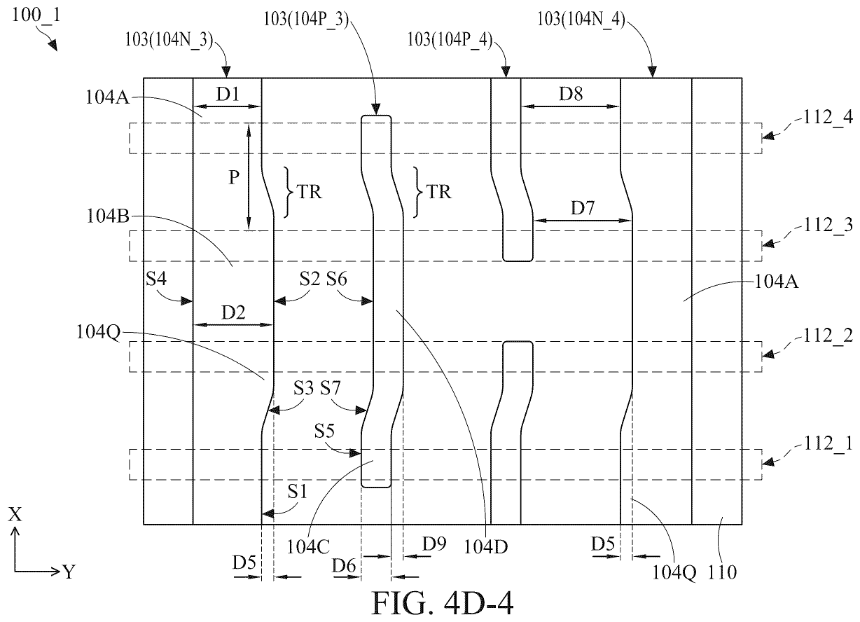

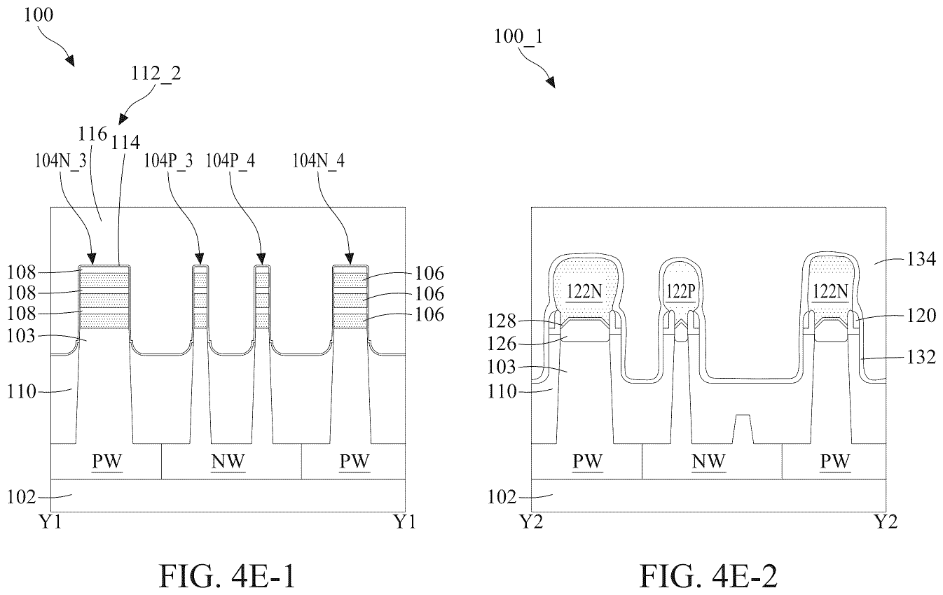

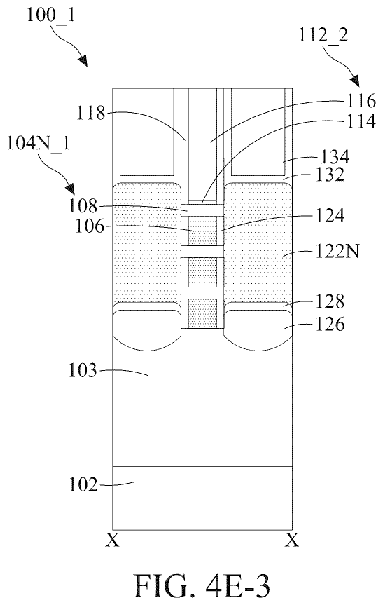

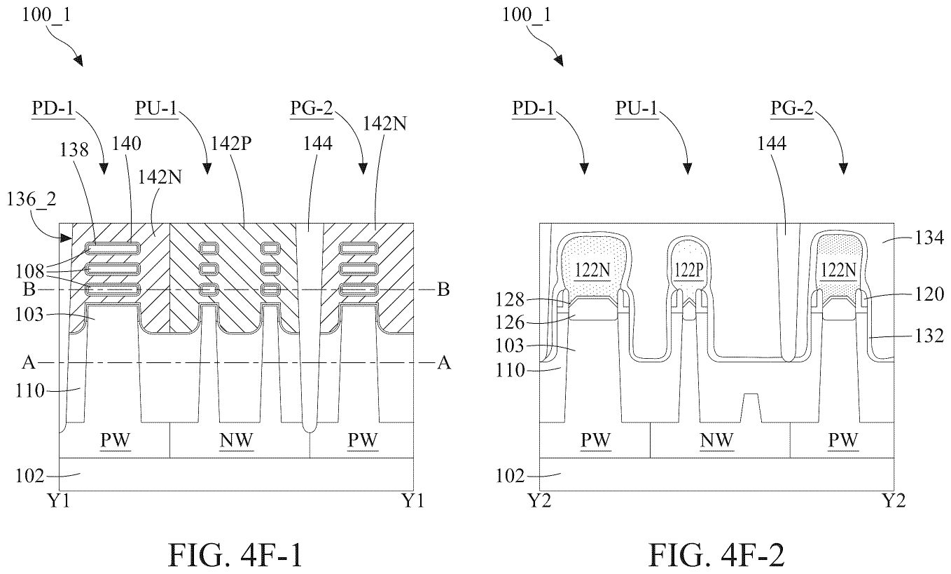

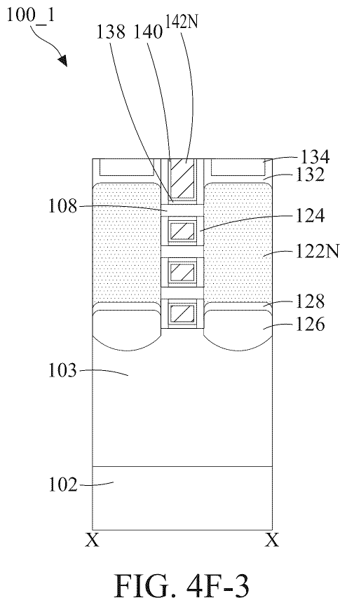

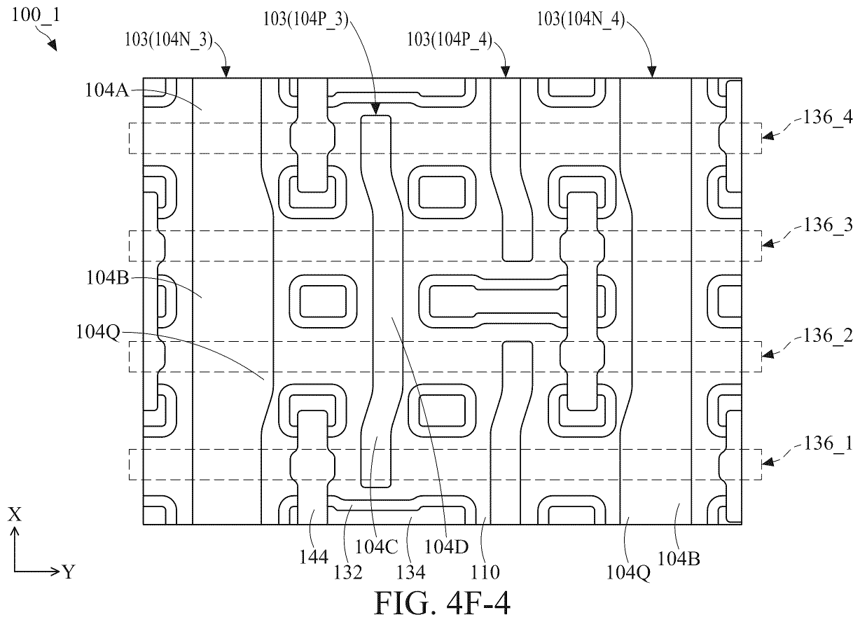

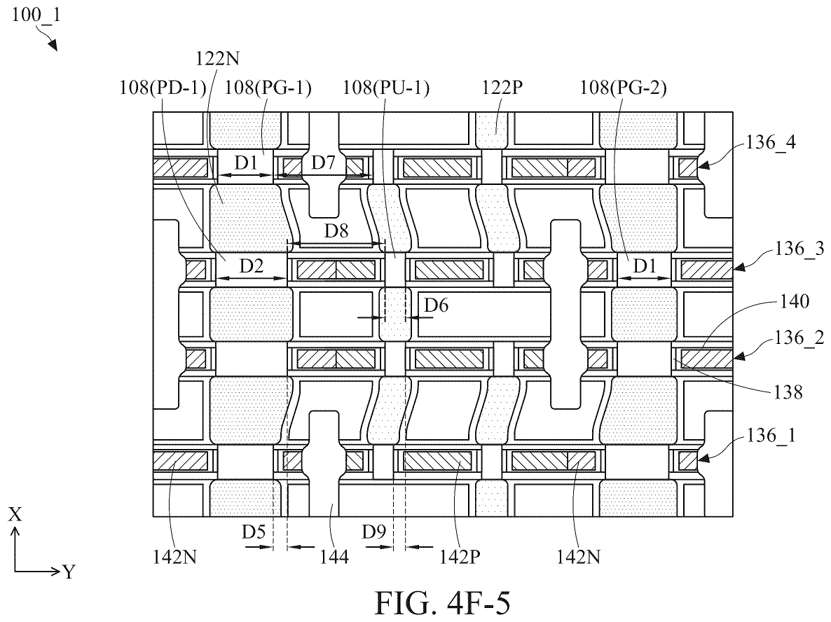

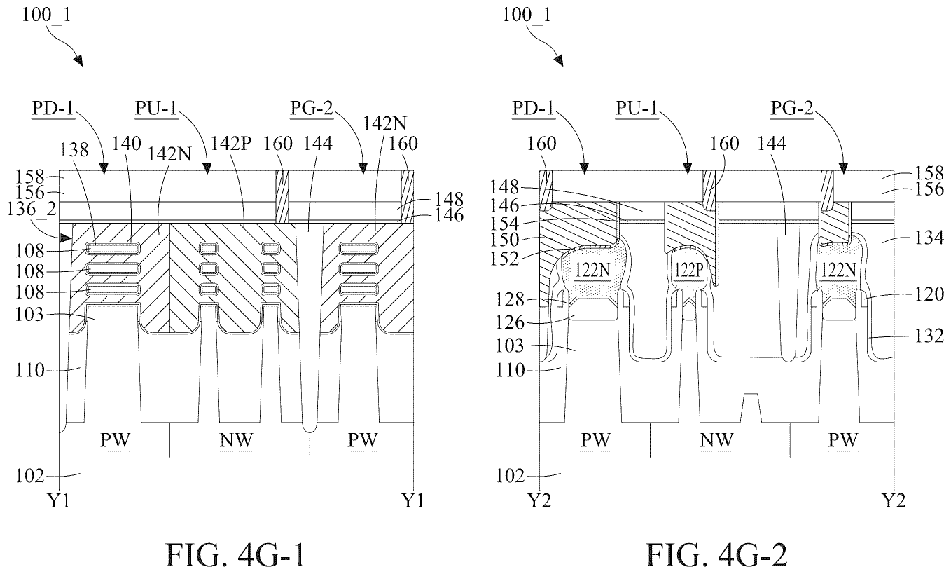

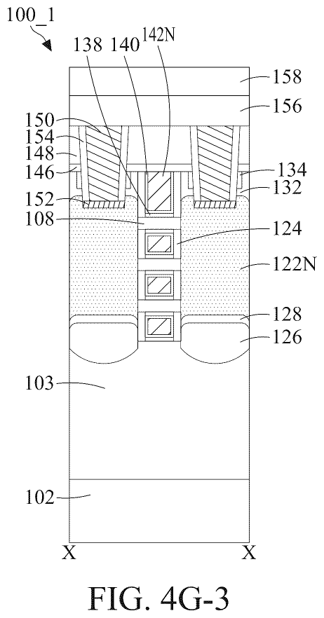

FIG. 4A illustrates a layout showing a group GP of the SRAM 30 in FIG. 1, in accordance with some embodiments of the disclosure. The group GP includes four SRAM cells 10_1, 10_2, 10_3 and 10_4 and is formed by active regions 104 (including 104N_1 to 104N_4 and 104P_1 to 104P_4) and gate stacks 136 (including 136_1 to 136_4). The active regions 104 may be the fin structure 104 as shown in FIG. 1. Each of the active regions 104 includes a lower fin element and sets of nanostructures over the lower fin element, in accordance with some embodiments. As the term is used herein, “a set of nanostructures” refers to active regions of a semiconductor structure that includes multiple semiconductor layers with cylindrical shape, bar shape and/or sheet shape.

The lower fin elements of the active regions 104 extend in the X direction, and the gate stacks 136 extend in the Y direction across the lower fin elements and wrap around the nanostructures, in accordance with some embodiments. In addition, the gate stacks 136 are cut into several segments electrically and physically isolated from each other, in accordance with some embodiments.

In some embodiments, the transistors within the SRAM cells 10_1, 10_2, 10_3 and 10_4 are nanostructure transistors in the N-type well regions NW and in the P-type well region PW. The N-type well regions NW are alternatively arranged with the P-type well regions PW, in accordance with some embodiments. The active regions 104N_1 to 104N_4 are formed in the N-type well regions NW, and the active regions 104P_1 to 104P_4 are formed in the P-type well regions PW, in accordance with some embodiments. In some embodiments, two active regions 104N or 104P are disposed in one well region PW or NW.

The two adjacent SRAM cells 10_1 and 10_3 are arranged in the same row of the cell array of the SRAM 30. The two adjacent SRAM cells 10_1 and 10_2 are arranged in the same column of the cell array of the SRAM 30. The two adjacent SRAM cells 10_3 and 10_4 are arranged in the same column of the cell array of the SRAM 30. In other words, the two adjacent SRAM cells 10_2 and 10_4 are arranged in the same row of the cell array of the SRAM 30.

In the SRAM cell 10_1, the pass-gate transistor PG-1 is formed at the cross point of the active region 104N_2 and the gate stack 136_1. The pull-down transistor PD-1 is formed at the cross point of the active region 104N_2 and the gate stack 136_2. The pass-gate transistor PG-2 is formed at the cross point of the active region 104N_1 and the gate stack 136_2. The pull-down transistor PD-2 is formed at the cross point of the active region 104N_1 and the gate stack 136_1. Moreover, in the SRAM cell 10_1, the pull-up transistor PU-1 is formed at the cross point of the active region 104P_2 and the gate stack 136_2. The pull-up transistor PU-2 is formed at the cross point of the active region 104P_1 and the gate stack 136_1. In addition, no functional transistors are formed at the cross point of the active regions 104P_1 and the gate stack 136_2 and at the cross point of the active regions 104P_2 and the gate stack 136_1.

Various contact plugs and their corresponding interconnect vias may be employed to electrically connect components in each SRAM cells 10_1 through 10_4. FIG. 4B illustrates the configuration of contact plugs on the layout of FIG. 4A, in accordance with some embodiments of the disclosure.

For example, in the SRAM cell 10_1, a bit line (BL) (not shown) may be electrically connected to the source terminal of the pass-gate transistor PG-1 through a contact plug 150_1, and a complementary bit line (BLB) (not shown) may be electrically connected to the source terminal of the pass-gate transistor PG-2 through a contact plug 150_2. Moreover, a power supply node VDD (not shown) may be electrically connected to the source terminal of the pull-up transistor PU-1 through a contact plug 150_3, and electrically connected to the source terminal of the pull-up transistor PU-2 through a contact plug 150_4. A ground VSS (not shown) may be electrically connected to the source terminal of the pull-down transistor PD-1 through a contact plug 150_5, and electrically connected to the source terminal of the pull-down transistor PD-2 through a contact plug 150_6.

In addition, In the SRAM cell 10_1, the drain terminals of the pull-up transistor PU-1 and the pull-down transistor PD-1 may be electrically connected to each other through a contact plug 150_7, and the drain terminals of the pull-up transistor PU-2 and the pull-down transistor PD-2 may be electrically connected to each other through a contact plug 150_8.

In some embodiments, the SRAM cell 10_2 is a duplicate cell for the SRAM cell 10_1 but flipped over the Y-axis, the SRAM cell 10_3 is a duplicate cell for the SRAM cell 10_1 but flipped over the X-axis, and the SRAM cell 10_4 is a duplicate cell for the SRAM cell 10_3 but flipped over the Y-axis.

The active regions 104N and 104P have jogs, in accordance with some embodiments. These jogs are defined between the neighboring gate stacks 136 and overlaps the contact plugs 150, in accordance with some embodiments. As a result, in some embodiments, the active regions 104 (e.g., 104N_1, 104P_2, 104P_3 and 104N_4) may have boomerang profiles, as shown in FIGS. 4A and 4B.

FIG. 4C illustrates an enlarged view of FIG. 4A to illustrate more details of the jog structures of the active regions 104, in accordance with some embodiments of the disclosure.

Each of the active regions 104N (e.g., 104N_3) is a semiconductor strip with a protruding portion 104Q, as shown in FIG. 4C, in accordance with some embodiments. The protruding portion 104Q extends in the Y direction toward the neighboring active region 104P (e.g., 104P_3), in accordance with some embodiments. That is, each of the active regions 104N includes a narrower portion 104A and a wider portion 104B, in accordance with some embodiments. The pass-gate transistors PG-1 and PG-2 are formed on the narrower portions 104A, and the pull-down transistors PD-1 and PD-2 are formed on the wider portions 104B, in accordance with some embodiments.

In some embodiments, the narrower portions 104A have a dimension D1 in the Y direction in a range from about 6 nm to about 65 nm. In some embodiments, the wider portions 104B have a dimension D2 in the Y direction. The dimension D2 is greater than dimension D1 and is in a range from about 6 nm to about 65 nm. In some embodiments, the gate stacks 136 (FIG. 4A) has a gate length (i.e., the dimension in the X direction) in a range from about 5 nm to about 29 nm. The ratio of the dimension D1 to the gate length in a range from about 0.6 to about 4.5. The ratio of the dimension D2 to the gate length in a range from about 0.6 to about 4.5.

In accordance with some embodiments of the present disclosure, by forming the active regions 104N with jog, independent adjustment of the performances of the n-channel nanostructure transistors (e.g., the pull-down transistors PD-1 and PD-2 and the pass-gate transistors PG-1 and PG-2) may be achieved, which may in turn optimally adjust the cell performance of the resulting SRAM cells, such as the current, operation voltage (Vmax), and/or the read margin metric, in accordance with some embodiments.

Because the channel width (e.g., the dimension D2) of the pull-down transistors PD-1 and PD-2 is greater than the channel width (e.g., the dimension D1) of the pass-gate transistors PG-1 and PG-2, the “beta ratio” of the saturation current (“Idsat”), that is the ratio of PD Idsat to PG Idsat, may increase, for example, be greater than 1, which may enhance the cell performance of the resulting SRAM cells, e.g., higher operation voltage (e.g., Vmax), higher cell current, broader read margin metric, and/or faster operation speed.

In some embodiments, the ratio (D2/D1) of the dimension D2 to the dimension D1 is in range from about 1.02 to about 3. If the ratio is too small (e.g., smaller than 1.02), the beta ratio may increase too little, the cell performance of the resulting SRAM may not significantly increase. If the ratio is too large (e.g., greater than 3), the cell performance (e.g., Vmax) of the resulting SRAM cells may decrease instead. In some embodiments, the ratio (D2/D1) is in range from about 1.02 to about 2.5. If the ratio is too large (e.g., greater than 2.5), the read margin metric may be overly compressed, so that the resulting SRAM cells may not have a good read/write margin balance.

In some embodiments where the active region is formed by one patterning process, the jog of the active region may occupy a certain distance in the X direction to convert the profile change of the active region. As a result, in some embodiments, the ratio (D2/D1) is in range from about 1.02 to about 2. If the ratio is too large (e.g., greater than 2), the jog transition may be too long, such that the active region may have an undesirable profile. In some embodiments where SRAM cells have a very small cell height (e.g., high-density SRAM cells), the ratio (D2/D1) is in range from about 1.02 to about 1.5.

In some embodiments, the distance D3 between the narrower portions 104A of neighboring active regions 104N (e.g., 104N_2 and 104N_3) is substantially equal to the distance D4 between the wider portions 104B of neighboring active regions 104N (e.g., 104N_2 and 104N_3), as shown in FIG. 4C. In some embodiments, the distance D3 is in a range from about 20 nm to about 60 nm. The ratio of the distance D3 to the gate length in a range from about 2 to about 5. In some embodiments, the distance D4 is in a range from about 20 nm to about 60 nm. The ratio of the distance D4 to the gate length in a range from about 2 to about 5.

In accordance with the embodiments of the present disclosure, because the distance D4 remains substantially equal to the distance D3, there may be no increased risk of merging between the N-type source/drain features of the neighboring pull-down transistors PD-1 and PD-2.

The sidewall S1 of the narrower portion 104A extending in the X direction is connected to the sidewall S2 of the wider portion 104B extending in the X direction through a connecting wall S3, in accordance with some embodiments. The connecting wall S3 extends a distance D5 (i.e., the dimension of the protruding portion 104Q) in the Y direction, as shown in FIG. 4C, in accordance with some embodiments. In some embodiments, the distance D5 is in a range from about 2 nm to about 30 nm. The ratio of the distance D5 to the gate length in a range from about 0.1 to about 2.

Each active region 104N (e.g., 104N_3) has a sidewall S4 facing neighboring active region 104N (e.g., 104N_2), in accordance with some embodiments. In some embodiments, the sidewall S4 extends continuously in the X direction and has no jog.

Each of the active regions 104P includes a first portion 104C and a second portion 104D offset from the first portion 104C, as shown in FIG. 4C, in accordance with some embodiments. That is, each of the active regions 104P (e.g., 104P_3) has a dent on the side facing the neighboring active region 104N (e.g., 104N_3) and a protrusion on the side facing the neighboring active region 104P (e.g., 104P_4), in accordance with some embodiments. The first portions 104C are dummy regions on which no functional transistors are formed, and the pull-up transistors PU-1 and PU-2 are formed on the second portions 104D, in accordance with some embodiments.

In some embodiments, the first portions 104C and the second portion 104D have the same dimension D6 in the Y direction. In some embodiment where the SRAM of FIGS. 4A-4C has a high-current design, the dimension D6 is less than the dimension D1 of the narrower portion 104A of the active region 104N, and is in a range from about 6 nm to about 35 nm. The ratio of the dimension D6 to the gate length in a range from about 0.6 to about 2.

In some embodiments, the distance D7 between the narrower portion 104A of the active region 104N and the first portion 104C of the active region 104P is substantially equal to the distance D8 between the wider portion 104B of the active region 104N and the second portion 104D of the active region 104P. In some embodiments, the distances D7 and D8 are in a range from about 20 nm to about 60 nm. The ratio of the distance D7 to the gate length in a range from about 2 to about 5. The ratio of the distance D8 to the gate length in a range from about 2 to about 5.

In accordance with the embodiments of the present disclosure, because the distance D8 remains substantially equal to the distance D7, there may be no increased risk of merging between the N-type source/drain feature of the pull-down transistors PD-1 or PD-2 and the P-type source/drain feature of the neighboring pull-up transistors PU-1 or PU-2.

The sidewall S5 of the first portion 104C extending in the X direction is connected to the sidewall S6 of the second portion 104D extending in the X direction through a connecting wall S7, in accordance with some embodiments. The connecting wall S7 extends a distance D9 in the Y direction, as shown in FIG. 4C, in accordance with some embodiments. In some embodiments, the distance D9 is in a range from about 2 nm to about 15 nm. The ratio of the distance D9 to the gate length in a range from about 0.1 to about 2. In some embodiments, the connecting walls S7 are aligned with the connecting walls S3. In some embodiments, the ratio (D5/D9) of the distance D5 to the distance D9 is equal to or greater than 1.

In some embodiments, the distance D10 between the neighboring active regions 104P (e.g., 104P_3 and 104P_4) is equal to or greater than the distance D8 between the wider portion 104B of the active region 104N and the second portion 104D of the active region 104P.

Referring back to FIG. 4A, FIG. 4A illustrates reference cross-sections that are used in later figures, in accordance with some embodiments. Cross-section X-X is in a plane parallel to the longitudinal axis (X direction) of an active region 104 and through the active region 104. Cross-section Y1-Y1 is in a plane parallel to the longitudinal axis (Y direction) of a gate stack 136 and through the gate stack 136_2. Cross-section Y2-Y2 is in a plane parallel to the longitudinal axis (Y direction) of a gate stack 136 and across the source/drain regions of the active regions 104 (e.g., the source terminals of the pull-down transistors PD-1).

FIGS. 4D-1 through 4G-3 are cross-sectional views illustrating the formation of a semiconductor structure 100_1 of an SRAM cell at various intermediate stages, in which FIGS. 4D-1, 4E-1, 4F-1 and 4G-1 correspond to cross-section Y1-Y1, FIGS. 4D-2, 4E-2, 4F-2 and 4G-2 correspond to cross-section Y2-Y2, and FIGS. 4D-3, 4E-3, 4F-3 and 4G-3 correspond to cross-section X-X, in accordance with some embodiments.

FIGS. 4D-1, 4D-2 and 4D-3 illustrate a semiconductor structure 100_1 after the formation of fin structures 104, an isolation structure 110, dummy gate structures 112, in accordance with some embodiments. FIG. 4D-4 is a plan view corresponding to plan A-A of FIG. 4D-1. Plan A-A cuts through the lower fin elements 103.

A substrate 102 is provided, as shown in FIGS. 4C-1, 4C-2 and 4C-3, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

N-type well regions NW and P-type well regions PW are formed in the substrate 102, as shown in FIGS. 4D-1 and 4D-2, in accordance with some embodiments. In some embodiments, the N-type well regions NW and the P-type well regions PW are stacked in such a way that they alternate, and they have different electrically conductive types. In some embodiments, the N-type well regions NW and the P-type well regions PW are formed by ion implantation processes. For example, a patterned mask layer (such as photoresist layer and/or hard mask layer) is formed to cover regions of the substrate 102 where the P-type well regions are predetermined to be formed, and then n-type dopants (such as phosphorus or arsenic) are implanted into the substrate 102, thereby forming the N-type well regions NW, in accordance with some embodiments. Similarly, a patterned mask layer (such as photoresist layer and/or hard mask layer) is formed to cover regions of the substrate 102 where the N-type well regions are predetermined to be formed, and then p-type dopants (such as boron or BF2) are implanted into the substrate 102, thereby forming the P-type well regions PW, in accordance with some embodiments.

Active regions 104 (including 104N and 104P) are formed over the substrate 102, as shown in FIGS. 4D-1 to 4D-4, in accordance with some embodiments. The active region 104N_3 and the active region 104N_4 are formed over respective two P-type well regions PW, while the active regions 104P_3 and 104P_4 are formed over the N-type region NW between the two P-type well regions PW, in accordance with some embodiments. In some embodiments, the active regions 104N and 104P extend in the X direction. That is, the active regions 104N and 104P have longitudinal axes parallel to the X direction, in accordance with some embodiments.

The formation of the 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor device (such as a nanostructure transistor), in accordance with some embodiments.

In some embodiments, the thickness of each of the first semiconductor layers 106 is in a range from about 3 nm to about 20 nm, such as about 4 nm to about 12 nm. In some embodiments, the thickness of each of the second semiconductor layers 108 is in a range from about 2 nm to about 20 nm, such as about 2 nm to about 10 nm. Although three first semiconductor layers 106 and three second semiconductor layers 108 are shown in FIGS. 4D-1 to 4D-3, the numbers are not limited to three, and can be 1, 2, or more than 3, and less than 10.

The epitaxial stack including the first semiconductor layers 106 and the second semiconductor layers 108 and underlying well regions NW and PW are patterned into the active regions 104N and 104P, in accordance with some embodiments. In some embodiments, the patterning process includes forming a patterned hard mask layer (not shown) over the epitaxial stack using a photolithography process. An etching process is then performed to remove portions of the epitaxial stack and well regions NW and PW uncovered by the patterned hard mask layer, thereby forming trenches and the active regions 104N and 104P protruding from between the trenches, in accordance with some embodiments. The etching process may be an anisotropic etching process, e.g., dry plasma etching.

The portion of the substrate 102 protruding from between the trenches forms lower fin elements 103 of the active regions 104N and 104P, in accordance with some embodiments. A remainder of the epitaxial stack (including the first semiconductor layers 106 and the second semiconductor layers 108) forms the upper fin elements of the active regions 104N and 104P over the respective lower fin elements 103, in accordance with some embodiments.

FIG. 4D-4 illustrates the profiles and the configurations of the lower fin elements 103 of the active regions 104N and 104P, which are similar to that of the active regions 104N and 104P described above in FIGS. 4A-4C, in accordance with some embodiments. Therefore, the repeated parts will not be described again. It should be noted that due to the characteristics of the photolithography and etching processes, the jog of the active region may occupy a certain distance (e.g., transition zone TR) to convert its profile changes. The jog with a transition zone TR may be referred to as “smooth jog”. In some embodiments, the connecting walls S3 and S7 may be linear sidewalls that are inclined between the X direction and the Y direction, or may be curved sidewalls (e.g., having smiling profiles), as shown in FIG. 4D-4, in accordance with some embodiments. The greater the dimension of jog (e.g., distance D5 and D9), the longer the transition zones TR is, in accordance with some embodiments.

In some other embodiments, by more than one patterning processes, the active regions 104 may be formed to have jogs without transition zones, having substantially the same profile as the active regions 104 of the layout as shown in FIGS. 4A-4C. The jog without transition zones TR may be referred to as “sharp jog”.

A cutting process is performed on the active regions 104P (e.g., 104P_3 and 104P_4) to cut the active regions 104P into several segments that are isolated from each other, as shown in FIGS. 4D-2 and 4D-4, in accordance with some embodiments. The cutting process may include photolithography and etching processes. In the cutting process, the upper fin elements of the active regions 104P are removed, and the lower fin elements 103 of the active regions 104P are also recessed, in accordance with some embodiments.

An isolation structure 110 is formed to surround the lower fin elements 103 of the active regions 104N and 104P, as shown in FIGS. 4D-1 and 4D-2, in accordance with some embodiments. The isolation structure 110 is configured to electrically isolate active regions 104N and 104P and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide, silicon nitride, silicon oxynitride (SiON), another suitable insulating material, multilayers thereof, and/or a combination thereof. In some embodiments, the insulating material is deposited using includes CVD (such as low-pressure CVD (LPCVD), plasma-enhanced CVD (PECVD), high density plasma CVD (HDP-CVD), high aspect ratio process (HARP), or flowable CVD (FCVD)), atomic layer deposition (ALD), another suitable technique, and/or a combination thereof.

A planarization process is performed on the insulating material to remove the insulating material from the tops of the active regions 104N and 104P, in accordance with some embodiments. The planarization may be chemical mechanical polishing (CMP), etching back process, or a combination thereof. The insulating material is then recessed by an etching process (such as dry plasma etching and/or wet chemical etching) until the upper fin elements of the active regions 104N and 104P are exposed, in accordance with some embodiments.

Dummy gate structures 112 (including 112_1 to 112_4) are formed over the semiconductor structure 100_1, as shown in FIGS. 4D-1, 4D-3 and 4D-4, in accordance with some embodiments. The dummy gate structures 112 extend across and surrounds the channel regions of the active regions 104N and 104P and the isolation structure 110, in accordance with some embodiments. The dummy gate structures 112 are configured as sacrificial structures and will be replaced with gate stacks (136_1 to 136_4 shown in FIG. 4A), in accordance with some embodiments. In some embodiments, the dummy gate structures 112 extend in the Y direction. That is, the dummy gate structures 112 have longitudinal axes parallel to the Y direction, in accordance with some embodiments.

In some embodiments, the connecting walls S3 and S7 are located between the adjacent dummy gate structures 112, as shown in FIG. 4D-4. In some embodiments, the transition zones TR may be less than a pitch P of the dummy gate structures 112, for example, approximately half the pitch P.

Each of the dummy gate structures 112 includes a dummy gate dielectric layer 114 and a dummy gate electrode layer 116 formed over the dummy gate dielectric layer 114, as shown in FIGS. 4A-1 and 4A-3, in accordance with some embodiments. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HAlO, and/or a combination thereof. In some embodiments, the dielectric material is formed using ALD, CVD, thermal oxidation, physical vapor deposition (PVD), another suitable technique, and/or a combination thereof.

In some embodiments, the dummy gate electrode layer 116 is made of semiconductor material such as polysilicon, poly-silicon germanium. In some embodiments, the dummy gate electrode layer 116 is made of a conductive material such as metallic nitrides, metallic silicides, metals, and/or a combination thereof. In some embodiments, the material for the dummy gate electrode layer 116 is formed using CVD, another suitable technique, and/or a combination thereof.

In some embodiments, the formation of the dummy gate structures 112 includes globally and conformally depositing a dielectric material for the dummy gate dielectric layer 114 over the semiconductor structure 100_1, depositing a material for the dummy gate electrode layer 116 over the dielectric material, planarizing the material for the dummy gate electrode layer 116, and patterning the dielectric material and the material for the dummy gate electrode layer 116 into the dummy gate structures 112. The patterning process includes forming a patterned hard mask layer (not shown) over the material for the dummy gate electrode layer 116 to cover the channel regions of the active regions 104N and 104P, in accordance with some embodiments. The material for the dummy gate electrode layer 116 and dielectric material, uncovered by the patterned hard mask layer, is etched away until the source/drain regions of the active regions 104N and 104P are exposed, in accordance with some embodiments.

FIGS. 4E-1, 4E-2 and 4E-3 illustrate a semiconductor structure 100_1 after the formation of gate spacer layers 118, fin spacer layers 120, the source/drain features 122N and 122P, inner spacer layers 124, semiconductor isolation features 126, dielectric isolation features 128, a contact etching stop layer 132 and a first interlayer dielectric layer 134, in accordance with some embodiments.

The gate spacer layers 118 are formed on the opposite sides of the dummy gate structures 112, and fin spacer layers 120 are formed along opposite sidewalls of the active regions 104, as shown in FIGS. 4E-2 and 4E-3, in accordance with some embodiments. The gate spacer layers 118 extend in the Y direction and across the active regions 104 and the isolation structure 110, in accordance with some embodiments. The gate spacer layers 118 are used to offset the subsequently formed source/drain features and separate the source/drain features from the gate structure, in accordance with some embodiments. The fin spacer layers 120 extend in the X direction, in accordance with some embodiments. The fin spacer layers 120 may be used to confine the growth of epitaxial material to prevent neighboring epitaxial material from merging with each other, in accordance with some embodiments.

In some embodiments, the gate spacer layers 118 and the fin spacer layers 120 are made of a silicon-containing dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the formation of the gate spacer layers 118 and the fin spacer layers 120 includes globally and conformally depositing a dielectric material over the semiconductor structure 100_1 using ALD, CVD (such as LPCVD, PECVD, HDP-CVD or HARP), another suitable method, and/or a combination thereof, followed by an anisotropic etching process.

The vertical portions of the dielectric material left remaining on the opposite sides of the dummy gate structures 112 serve as the gate spacer layers 118, in accordance with some embodiments. The vertical portions of the dielectric material left remaining on the opposite sides of the active regions 104N and 104P serve as fin spacer layers 120, in accordance with some embodiments.

Source/drain features 122N and 122P are formed in and/or over the source/drain regions of the active regions 104N and 104P, as shown in FIGS. 4E-2 and 4E-3, in accordance with some embodiments. The formation of the source/drain features 122 includes recessing the source/drain regions of the active regions 104N and 104P using the dummy gate structures 112 and the gate spacer layers 118 as masks to form source/drain recesses on opposite sides of the dummy gate structures 112, in accordance with some embodiments. The source/drain recesses may extend into the lower fin elements 103, in accordance with some embodiments. In some embodiments, the recessing process includes an anisotropic etching process such as dry plasma etching, an isotropic etching process such as dry chemical etching, remote plasma etching or wet chemical etching, or a combination thereof. In some embodiments, the fin spacer layers 120 and the isolation structure 110 are also recessed in the etching process.

Afterward, an etching process is performed to laterally recess, from the source/drain recesses, the first semiconductor layers 106 of the active regions 104N and 104P thereby forming notches, and then inner spacer layers 124 are formed in the notches, as shown in FIG. 4E-3, in accordance with some embodiments. The inner spacer layers 124 are formed to abut the recessed side surfaces of the first semiconductor layers 106, in accordance with some embodiments. In some embodiments, the inner spacer layers 124 extend directly below the gate spacer layers 118.

The inner spacer layers 124 may avoid the source/drain features and the gate stack from being in direct contact and are configured to reduce the parasitic capacitance between the gate stack and the source/drain features (i.e., Cgs and Cgd), in accordance with some embodiments. In some embodiments, the inner spacer layers 124 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN).

In some embodiments, the inner spacer layers 124 are formed by depositing a dielectric material for the inner spacer layers 124 over the semiconductor structure 100_1 to fill the notches, and then etching back the dielectric material to remove the dielectric material outside the notches. Portions of the dielectric material left in the notches serve as the inner spacer layers 124, in accordance with some embodiments. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

Semiconductor isolation features 126 are formed in the source/drain recesses over the lower fin elements 103, as shown in FIGS. 4E-2 and 4E-3, in accordance with some embodiments. In some embodiments, the semiconductor isolation features 126 are made of an epitaxial semiconductor material such as non-doped silicon, formed by MBE, MOCVD, or VPE, another suitable technique, or a combination thereof.

Dielectric isolation features 128 are formed over the semiconductor isolation features 126 in the source/drain recesses, as shown in FIGS. 4E-2 and 4E-3, in accordance with some embodiments. In some embodiments, the dielectric isolation features 128 are in direct contact with the semiconductor isolation features 126 and the bottommost inner spacer layers 124.

In some embodiments, the dielectric isolation features 128 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, TaCN, or a combination thereof. In some embodiments, the dielectric isolation features 128 are deposited using a technique such as ALD, CVD (such as HDP-CVD, LPCVD or PECVD), another suitable technique, or a combination thereof, followed by an etching-back process.

Source/drain features 122N and 122P are formed over the dielectric isolation features 128 in the source/drain recesses, as shown in FIGS. 4E-2 and 4E-3, in accordance with some embodiments. The source/drain features 122N and 122P are formed on opposite sides of the dummy gate structures 112, in accordance with some embodiments. In some embodiments, the source/drain features 122N have a different electrically conductive type than the source/drain features 122P. The formation may include one or more epitaxial growth processes. These epitaxial growth processes may be MBE, MOCVD, or VPE, another suitable technique, or a combination thereof.

In some embodiments, the source/drain features 122N and the source/drain features 122P may be formed separately. For example, a patterned mask layer (such as a photoresist layer and/or a hard mask layer) may be formed to cover the semiconductor structure 100_1 over the N-type well regions NW, and then the source/drain features 122N are grown. Afterward, the patterned mask layer may be removed. Similarly, a patterned mask layer (such as a photoresist layer and/or a hard mask layer) is formed to cover the semiconductor structure 100_1 over the P-type well regions PW, and then the source/drain features 122P are grown. Afterward, the patterned mask layer may be removed.

In some embodiments, the source/drain features 122N and 122P are in-situ doped during the epitaxial processes. In some embodiments, the source/drain features 122N are doped with the n-type dopant during the epitaxial growth process. For example, the n-type dopant may be phosphorous (P) or arsenic (As). For example, the n-type source/drain features 122N may be the epitaxially grown silicon phosphorous (SiP), silicon carbon (SiC), silicon phosphorous carbon (SiPC), silicon phosphorous arsenic (SiPAs), silicon arsenic (SiAs), silicon (Si), or a combination thereof doped with phosphorous and/or arsenic. In some embodiments, the concentrations of the dopant (e.g., P) in the source/drain features 122N are in a range from about 2×10¹⁹ cm⁻³ to about 3×10²¹ cm⁻³.

In some embodiments, the source/drain features 122P are doped with the p-type dopant during the epitaxial growth process. For example, the p-type dopant may be boron (B) or BF2. For example, the p-type source/drain features 122P may be the epitaxially grown silicon germanium (SiGe), silicon germanium carbon (SiGeC), germanium (Ge), silicon (P), or a combination thereof doped with boron (B). In some embodiments, the concentrations of the dopant (e.g., B) in the source/drain features 122P are in a range from about 1×10¹⁹ cm⁻³ to about 6×10²⁰ cm⁻³. In some embodiments, the n-type source/drain features 122N and the p-type source/drain features 122P are made of different epitaxial materials. For example, the n-type source/drain features 122N are made of SiP, and the p-type source/drain features 122P are made of SiGe.

A contact etching stop layer 132 is formed the semiconductor structure 100_1 to cover the source/drain features 122N and 122P, as shown in FIGS. 4E-2 and 4E-3, in accordance with some embodiments. In some embodiments, the contact etching stop layer 132 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 132 is globally and conformally deposited over the semiconductor structure 100_1 using CVD (such as LPCVD, PECVD, HDP-CVD, or HARP), ALD, another suitable method, or a combination thereof.

Afterward, a first interlayer dielectric layer 134 is formed over the contact etching stop layer 132 to fill spaces between the dummy gate structures 112, as shown in FIGS. 4E-2 and 4E-3, in accordance with some embodiments. In some embodiments, the first interlayer dielectric layer 134 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the first interlayer dielectric layer 134 and the contact etching stop layer 132 are made of different materials and have a great difference in etching selectivity. In some embodiments, the dielectric material for the first interlayer dielectric layer 134 is deposited using such as CVD (such as HDP-CVD, PECVD, HARP or FCVD), another suitable technique, and/or a combination thereof. The dielectric materials for the contact etching stop layer 132 and the first interlayer dielectric layer 134 above the dummy gate electrode layer 116 are removed using such as CMP until the top surface of the dummy gate electrode layer 116 is exposed, in accordance with some embodiments.

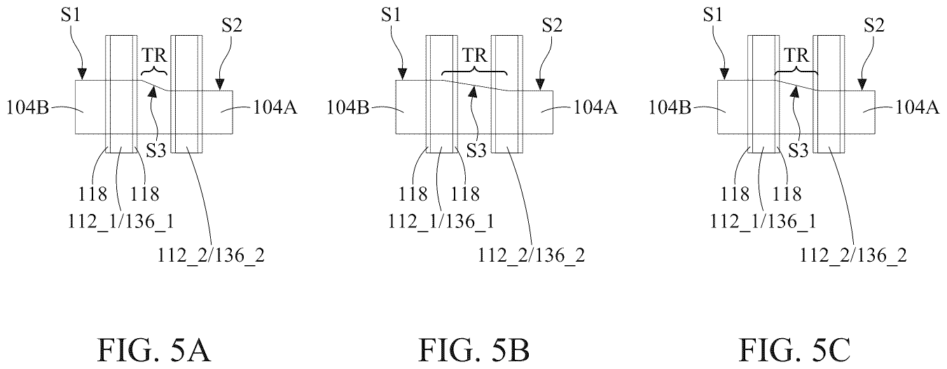

FIGS. 4F-1, 4F-2 and 4F-3 illustrate a semiconductor structure 100_1 after the formation of gate stacks 136 and gate isolation structures 144, in accordance with some embodiments. FIG. 4F-4 is a plan view corresponding to plan A-A of FIG. 4F-1. FIG. 4F-5 is a plan view corresponding to plan B-B of FIG. 4F-1. Plan B-B cuts through the second semiconductor layers 108.

The dummy gate structures 112 are removed using one or more etching processes to form gate trenches, in accordance with some embodiments. The gate trenches expose the channel regions of the active regions 104N and 104P, in accordance with some embodiments. In some embodiments, the gate trenches also expose the inner sidewalls of the gate spacer layers 118 facing the channel region, in accordance with some embodiments.

The first semiconductor layers 106 of the active regions 104N and 104P are removed using an etching process to form gaps, in accordance with some embodiments. The inner spacer layers 124 may be used as an etching stop layer in the etching process, which may protect the source/drain features 122N and 122P from being damaged. In some embodiments, the gaps also expose the inner sidewalls of the inner spacer layers 124 facing the channel region. The etching processes for removing dummy gate structures 116 and the first semiconductor layers 106 may be an anisotropic etching process such as dry plasma etching, an isotropic etching process such as dry chemical etching, remote plasma etching or wet chemical etching, and/or a combination thereof.

After the etching processes, the main surfaces of the second semiconductor layers 108 are exposed, in accordance with some embodiments. The exposed second semiconductor layers 108 of the active regions 104N and 104P form sets of nanostructures 108 that function as channel layers of the resulting semiconductor devices (e.g., nanostructure transistors such as GAA FETs), in accordance with some embodiments.

Final gate stacks 136 (including 136_1 to 136_4) are formed in the gate trenches and gaps, thereby wrapping around the nanostructures 108, as shown in FIGS. 4F-1, 4F-3, 4F-4 and 4F-5, in accordance with some embodiments. In some embodiments, the final gate stacks 136 extend in the Y direction. That is, the final gate stacks 136 have longitudinal axes parallel to the Y direction, in accordance with some embodiments. The final gate stacks 136 engage the channel region so that current can flow between the source/drain regions during operation. In some embodiments, each of the final gate stacks 136 includes an interfacial layer 138, a gate dielectric layer 140 and a metal gate electrode layer 142 (including 142N and 142P), as shown in FIGS. 4F-1, 4F-3 and 4F-5, in accordance with some embodiments.

In some embodiments, the interfacial layer 138 is made of a chemically formed silicon oxide. In some embodiments, the interfacial layer 138 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 103 is oxidized to form the interfacial layer 138, in accordance with some embodiments.

The gate dielectric layer 140 is formed conformally along the interfacial layer 138, the upper surface of the isolation structure 110, the sidewalls of the gate spacer layers 118, and the sidewalls of the inner spacer layers 124, in accordance with some embodiments. The gate dielectric layer 140 is made of a high-k dielectric layer. In some embodiments, the high-k dielectric layer is dielectric material with high dielectric constant (k value), for example, greater than 7.9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Si₃N₄, oxynitrides (SiON), a combination thereof, or another suitable material. The high-k dielectric layer may be deposited using ALD, PVD, CVD, and/or another suitable technique.

The metal gate electrode layers 142N are formed over the P-type well regions PW, and the metal gate electrode layers 142P are formed over the N-type well regions NW, in accordance with some embodiments. In some embodiments, the metal gate electrode layers 142N and 142P are made of more than one conductive material, such as a metal, metal alloy, conductive metal oxide and/or metal nitride, another suitable conductive material, and/or a combination thereof. For example, the metal gate electrode layers 142N and 142P may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layers 142N and 142P may be a multi-layer structure with various combinations of a diffusion barrier layer, work function layers with a selected work function to enhance the device performance (e.g., threshold voltage) for n-channel FETs and p-channel FETs, a capping layer to prevent oxidation of work function layers, a glue layer to adhere work function layers to the next layer, and a metal fill layer to reduce the total resistance of gate stacks, and/or another suitable layer. The metal gate electrode layers 142N and 142P may be formed using ALD, PVD, CVD, e-beam evaporation, or another suitable technique. The metal gate electrode layers 142N and 142P may be formed separately for n-channel FETs and p-channel FETs, which may use different work function materials. In alternative embodiments, the conductive material for the metal gate electrode layers 142N is the same as the conductive material for the metal gate electrode 142P.

A planarization process such as CMP may be performed on the semiconductor structure 100_1 to remove the materials of the gate dielectric layer 140 and the metal gate electrode layer 142N and 142P formed above the first interlayer dielectric layer 134, in accordance with some embodiments. The final gate stacks 136 that are wrapped around the nanostructures 108 combine with the neighboring source/drain features 122N or 122P to form nanostructure transistors.

The transistors formed on the nanostructures 108 (of the active regions 104N) in the P-type well regions PW are the n-channel nanostructure transistors, e.g., pull-down transistors PD-1 and PD-2 and pass-gate transistors PG-1 and PG-2, in accordance with some embodiments. The transistors formed on the nanostructures 108 (of the active regions 104P) in the N-type well regions NW are the p-channel nanostructure transistors, e.g., pull-up transistors PU-1 and PU-2, in accordance with some embodiments.

The nanostructures 108 of the pass-gate transistors PG-1 and PG-2 have a dimension D1 in the Y direction, which is substantially equal to the dimension D1 of the narrower portions 104A of the active regions 104N, in accordance with some embodiments. The nanostructures 108 of the pull-down transistors PD-1 and PD-2 have a dimension D2 in the Y direction, which is substantially equal to the dimension D2 of the wider portions 104B of the active regions 104N, in accordance with some embodiments. The dimension D2 is greater than the dimension D1 by the distance D5. The nanostructures 108 of the pull-up transistors PU-1 and PU-2 have a dimension D6 in the Y direction, which is substantially equal to the dimension D6 of the second portions 104D of the active regions 104P, in accordance with some embodiments.

In accordance with some embodiments of the present disclosure, because the nanostructures 108 of the pull-down transistors PD-1 and PD-2 are wider than the nanostructures 108 of the pass-gate transistors PG-1 and PG-2, the beta ratio of the saturation current may increase, which may enhance cell performance of the resulting SRAM cells, e.g., higher operation voltage (Vmax) and higher cell current, broader read margin metric, and/or faster operation speed.

Gate isolation structures 144 are formed in and/or through the final gate stacks 136, the gate spacer layers 118, the first interlayer dielectric layer 134 and the contact etching stop layer 132, as shown in FIGS. 4F-1, 4F-2, 4F-4 and 4F-5, in accordance with some embodiments. The gate stacks 136 are cut through by the gate isolation structures 144 into several segments which are physically and electrically isolated from each other, in accordance with some embodiments. The gate isolation structures 144 may be also referred to as cut metal gate (CMG) pattern.

The portions of the gate isolation structure 144 through the gate stack 136 extend to a deeper position than the portions of the gate isolation structures 144 through the first interlayer dielectric layer 134, as shown in FIGS. 4F-1 and 4F-2, in accordance with some embodiments. In some embodiments, as shown in FIGS. 4F-4 and 4F-5, the portions of the gate isolation structure 144 through the gate stack 136 are wider than the portions of the gate isolation structures 144 through the first interlayer dielectric layer 134, which may reduce the overlapping area between the gate stack 136 and the source/drain features 122N/122P, thereby reducing the parasitic capacitance of the resulting SRAM cells.

The gate isolation structures 144 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or high-k dielectric material such as LaO, AlO, AlON, ZrO, HfO, ZnO, ZrN, ZrAlO, TiO, TaO, YO, TaCN, or a combination thereof.

The formation of the gate isolation structures 144 includes patterning the semiconductor structures 100_1 to form gate-cut openings (where the gate isolation structures 144 are to be formed) using photolithography and etching processes. The etch processes may include dry etching such as reactive ion etch (RIE), neutral beam etch (NBE), inductive coupled plasma (ICP) etch, capacitively coupled plasma (CCP) etch, another suitable method, or a combination thereof. The formation of the gate isolation structures 144 further includes depositing a dielectric material for the gate isolation structures 144 to overfill the gate-cut openings, in accordance with some embodiments. In some embodiments, the deposition process is ALD, CVD (such as LPCVD, PECVD, HDP-CVD, or HARP), another suitable technique, or a combination thereof. Afterward, a planarization process is performed on the dielectric material for the gate isolation structures 144 until the first interlayer dielectric layer 134 is exposed, in accordance with some embodiments. The planarization may be CMP, etching back process, or a combination thereof.

FIGS. 4G-1, 4G-2 and 4G-3 illustrate a semiconductor structure 100_1 after the formation of an etching stop layer 146, a second interlayer dielectric layer 148, contact plugs 150, an etching stop layer 156, a second interlayer dielectric layer 158, and vias 160, in accordance with some embodiments.

An etching stop layer 146 and a second interlayer dielectric layer 148 are sequentially formed over the semiconductor structure 100_1, as shown in FIGS. 4G-1 to 4G-3, in accordance with some embodiments. In some embodiments, the etching stop layer 146 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the second interlayer dielectric layer 148 is made of dielectric material, such as USG, BPSG, FSG, PSG, BSG, and/or another suitable dielectric material. In some embodiments, the etching stop layer 146 and the second interlayer dielectric layer 148 are deposited using CVD (such as HDP-CVD, PECVD, HARP or FCVD), another suitable technique, or a combination thereof.

The contact plugs 150 are formed through the second interlayer dielectric layer 148, the etching stop layer 146, the first interlayer dielectric layer 134 and the contact etching stop layer 132, in accordance with some embodiments. The contact plugs 150 land on the source/drain features 122N/122P, in accordance with some embodiments. In some embodiments, the formation of the contact plugs 150 includes patterning the semiconductor structure 100_1 to form contact openings (where the contact plugs 150 are to be formed) using photolithography and etching processes until the source/drain features 122N/122P are exposed. The etch process may include dry etching such as RIE, NBE, ICP etch, CCP etch, another suitable method, or a combination thereof.

Silicide layers 152 are formed on the exposed surfaces of the source/drain features 122N and 122P, in accordance with some embodiments. In some embodiments, the silicide layers 152 are made of WSi, NiSi, TiSi and/or CoSi. In some embodiments, the formation of the silicide layers 152 includes depositing a metal material followed by one or more annealing processes. The semiconductive material (e.g., Si) from the source/drain features 122N and 122P reacts with the metal material to form the silicide layers 152, in accordance with some embodiments. Unreacted metal material is then removed, e.g., using wet etching.

Contact liners 154 are formed along the sidewalls of the contact openings using a deposition process and an etching back process, in accordance with some embodiments. In some embodiments, the contact liners 154 are made of an insulating material such as a dielectric material (e.g., SiC, LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si).

Afterward, one or more conductive materials for the contact plugs 150 are deposited to overfill the contact openings, in accordance with some embodiments. In some embodiments, one or more conductive materials are deposited using CVD, PVD, e-beam evaporation, ALD, ECP, ELD, another suitable method, or a combination thereof to overfill the contact openings. The one or more conductive materials over the second interlayer dielectric layer 148 are planarized using, for example, CMP.

The contact plugs 150 may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

An etching stop layer 156 and a third interlayer dielectric layer 158 are sequentially formed over the semiconductor structure 100_1, as shown in FIGS. 4G-1 to 4G-3, in accordance with some embodiments. In some embodiments, the etching stop layer 156 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the third interlayer dielectric layer 158 is made of dielectric material, such as USG, BPSG, FSG, PSG, BSG, and/or another suitable dielectric material. In some embodiments, the etching stop layer 156 and the third interlayer dielectric layer 158 are deposited using CVD (such as HDP-CVD, PECVD, HARP or FCVD), another suitable technique, or a combination thereof.

Vias 160 are formed to land on the contact plugs 150 and the gate stacks 136, as shown in FIGS. 4G-1 and 4G-2, in accordance with some embodiments. The vias 160, electrically connected to source/drain terminals of the nanostructure transistors through the contact plugs 150, may be also referred to as source/drain vias (VS or VD), in accordance with some embodiments. The vias 160, electrically connected to the gate terminals of the nanostructure transistors, may be also referred to as gate vias (VG).

In some embodiments, the formation of the vias 160 includes patterning the semiconductor structure 100_1 to form via openings (where the vias 160 are to be formed) using photolithography and etching processes. The etching process may include dry etching such as RIE, NBE, ICP etch, CCP etch, another suitable method, or a combination thereof. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 152 are planarized using, for example, CMP.

The vias 160 may have a multilayer structure. For example, a barrier/adhesive layer (not shown) may optionally be deposited along the sidewalls and the bottom surfaces of the via openings. The barrier layer may be made of Ta, TaN, Ti, TiN, CoW, another suitable material, or a combination thereof. A metal bulk layer is then deposited on the barrier/adhesive layer (if formed) to fill the remainder of the via openings. In some embodiments, the metal bulk layer is made of one or more conductive materials, such as Co, Ni, W, Ti, Ta, Cu, Rh, Ir, Pt, Al, Ru, Mo, or a combination thereof.

The semiconductor structure 100_1 may undergo further frontside BEOL processes to form various interconnection conductive features (not shown) over the semiconductor structure 100_1, such as metal layers and vias between neighboring two metal layers. In accordance with the embodiments of the present disclosure, without increasing the cell height of the SRAM cell, by forming the active regions 104N and 104P with jogs, the channel width of the pull-down transistor is increased, thereby enhancing the cell performance of the resulting SRAM cells while preventing the increase in the risk of source/drain merging.

FIGS. 5A, 5B and 5C are plan views illustrating active regions with smooth jogs, in accordance with some embodiments of the disclosure. The embodiments of FIGS. 5A, 5B and 5C are similar to the embodiments of FIGS. 4A to 4G-3, except for the dimension of the transition zone TR of the active region.

Due to the characteristics of the photolithography and etching processes, the transition zones TR of the active region 104N may have various dimensions. For example, in some embodiments, the transition zones TR of the active regions 104N are confined between the gate spacer layers 118, and do not overlap the gate spacer layers 118, as shown in FIG. 5A. In some embodiments, the transition zones TR of the active regions 104N extend directly under neighboring dummy gate structures 112 (or neighboring gate stacks 136), as shown in FIG. 5B. In some embodiments, the transition zones TR of the active regions 104N are confined between the neighboring dummy gate structures 112 (or neighboring gate stacks 136), and do not overlap neighboring dummy gate structures 112 (or neighboring gate stacks 136), as shown in FIG. 5C. Although FIGS. 5A, 5B and 5C only illustrate the active regions 104N with various smooth jogs, the active region 104P have also similar jog profiles.

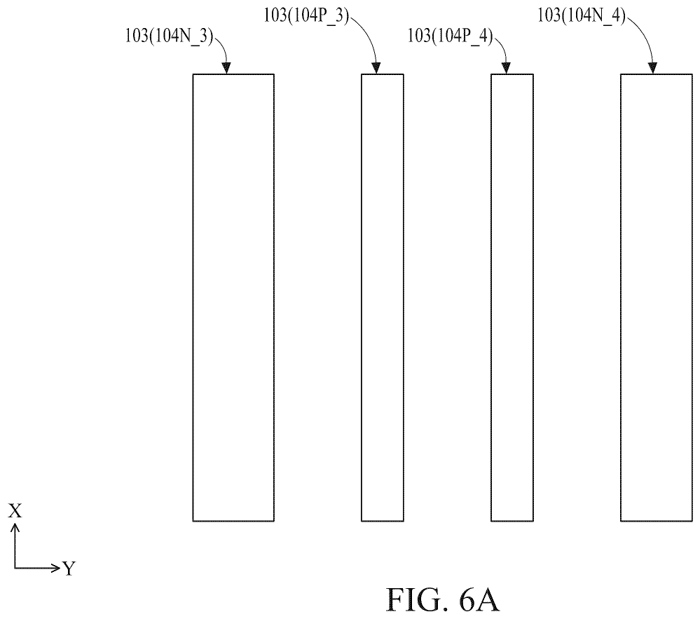

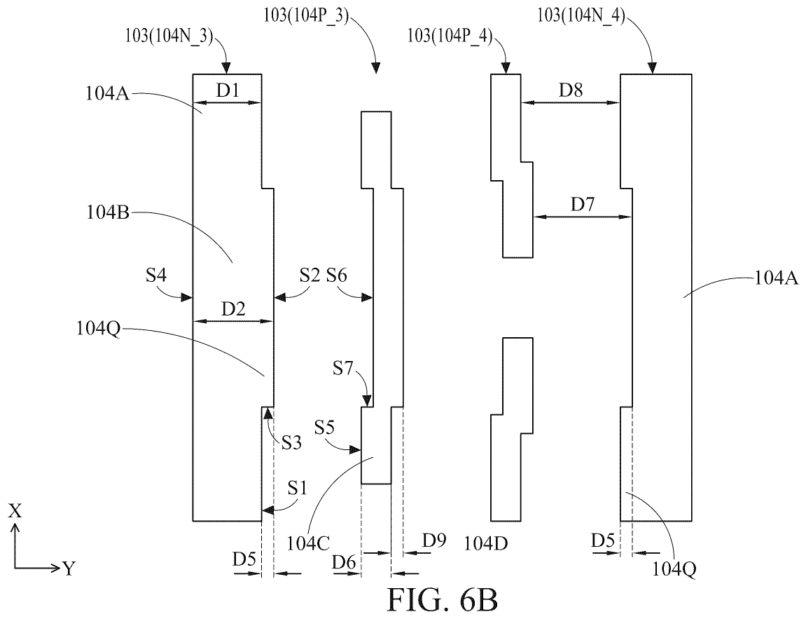

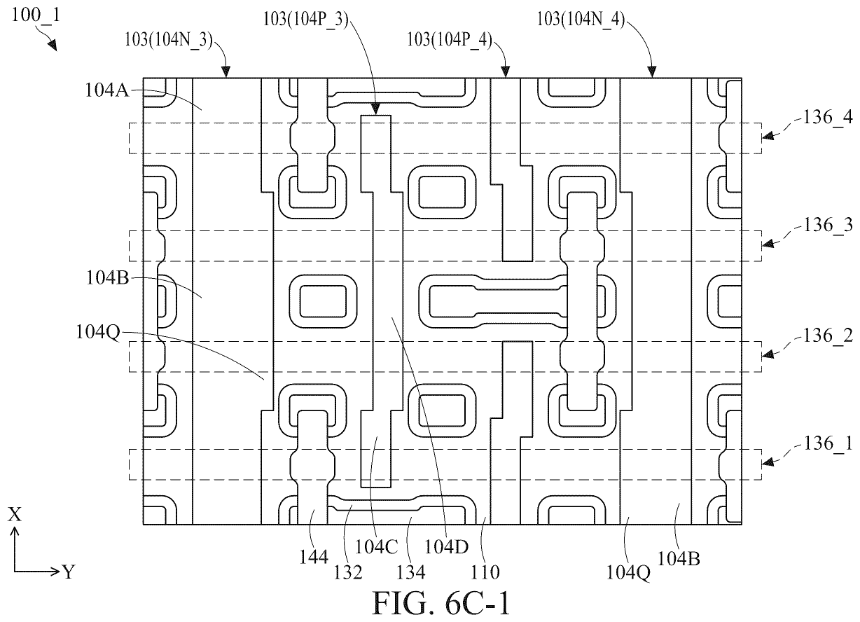

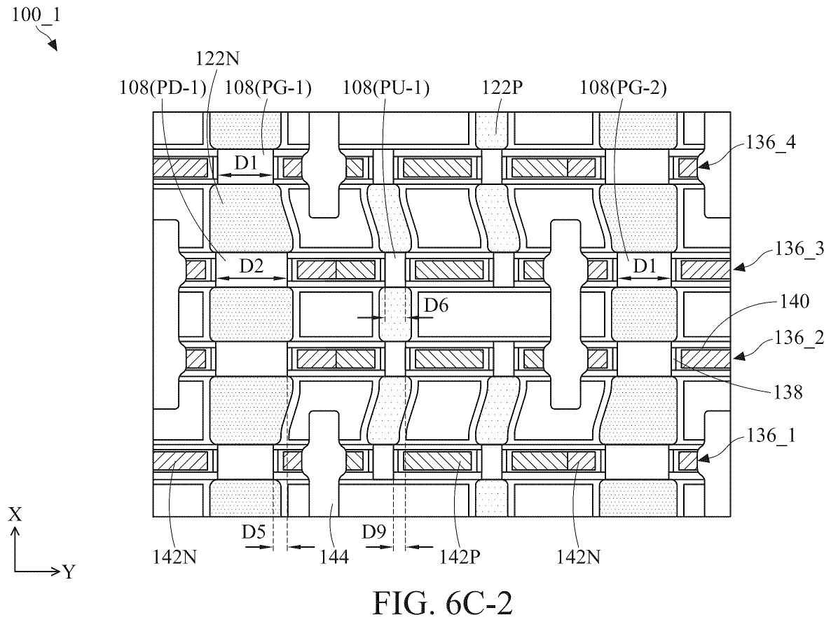

FIGS. 6A and 6B are plan views illustrating the formation of active regions with sharp jogs, in accordance with some embodiments of the disclosure. FIGS. 6A and 6B are plan views corresponding to plan A-A.

The formation of the active regions 104N and 104P may be performed using two patterning processes, in accordance with some embodiments. In some embodiments, a first patterning process (including photolithography and etching processes) is performed on the epitaxial stack (including the first semiconductor layers 106 and the second semiconductor layers 108) and underlying well regions NW and PW to form the active regions 104N and 104P, in accordance with some embodiments. As shown in FIG. 6A, the active regions 104N and 104P are semiconductor strips without jogs, in accordance with some embodiments.

A second patterning process (including photolithography and etching processes) is then performed on the active regions 104N and 104P to partially cut off the active regions 104N and 104P, so that jogs are formed on the sides of the active regions 104N and 104P, as shown in FIG. 6B, in accordance with some embodiments. The mask patterns used in the first and second photolithography processes do not have jog profiles, and thus the active regions 104N and 104P may be formed with sharp jogs, in accordance with some embodiments.

As shown in FIG. 6B, the lower fin elements 103 of the active regions 104N and 104P may have substantially the same profile as the active regions 104N and 104P of the layout shown in FIG. 4A, in accordance with some embodiments. The connecting walls S3 and S7 extend in the Y direction, in accordance with some embodiments. In some embodiments, the connecting walls S7 are aligned with the connecting walls S3.

FIGS. 6C-1 and 6C-2 are plan views of a semiconductor structure 100_1 of SRAM cells corresponding to plan A-A and plan B-B, respectively, in accordance with some embodiments of the disclosure. The steps described above in FIGS. 4D-1 to 4G-3 may be performed on the active regions 104N and 104P of FIG. 6B, thereby forming the nanostructure transistors of SRAM cells, as shown in FIGS. 6C-1 and 6C-2, in accordance with some embodiments.

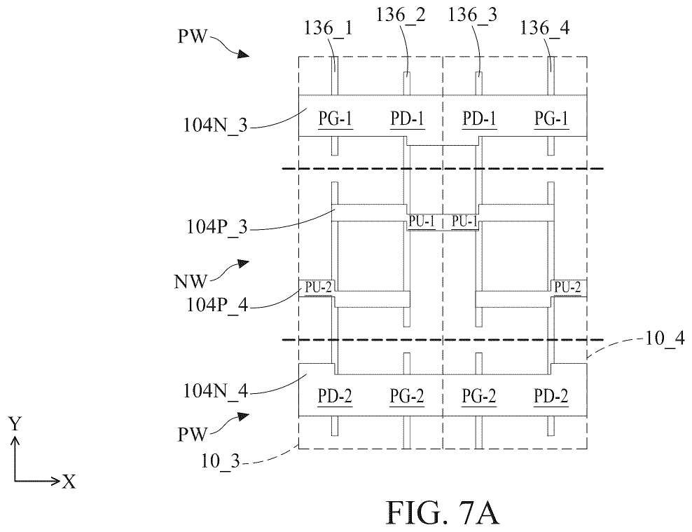

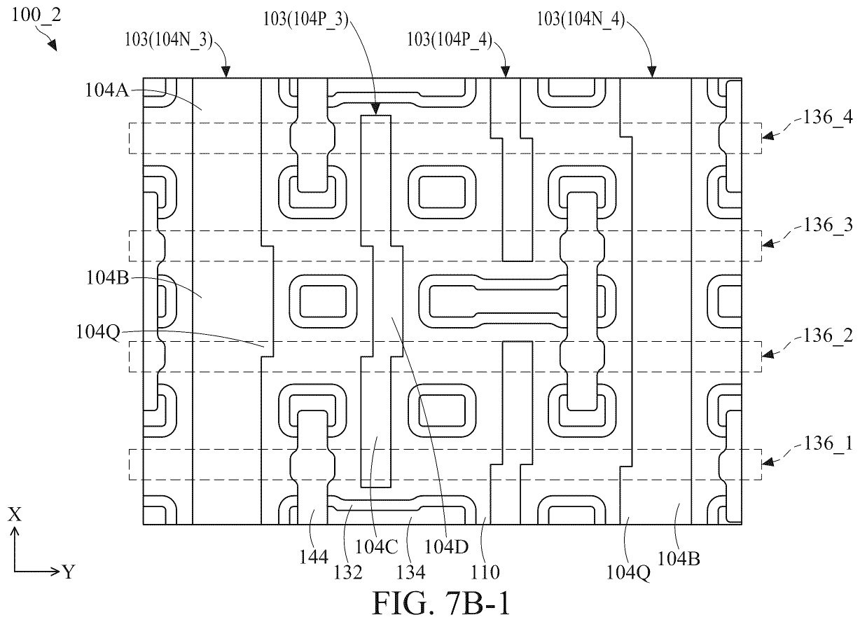

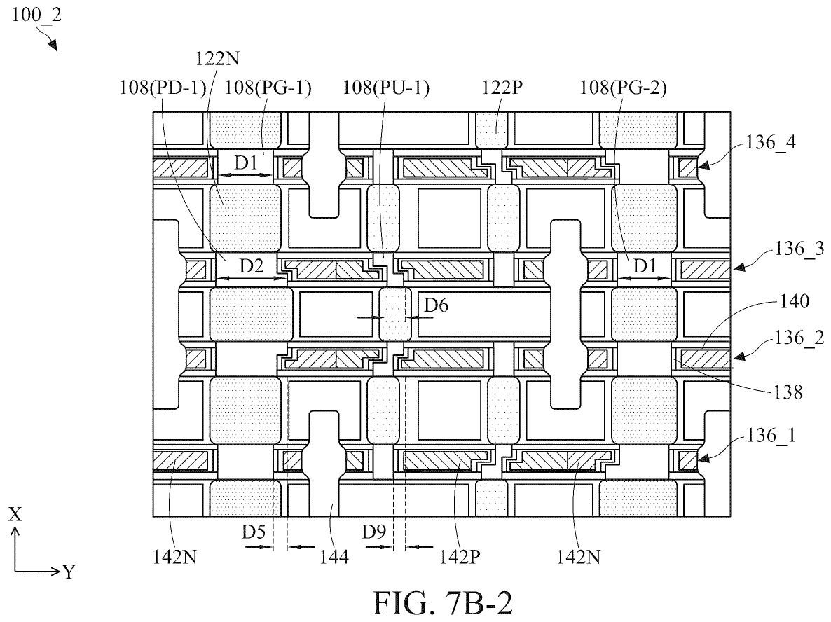

FIG. 7A illustrates a layout showing half of a group GP of the SRAM in FIG. 2, in accordance with some embodiments of the disclosure. FIGS. 7B-1 and 7B-2 are plan views of a semiconductor structure 100_2 of the SRAM cells of FIG. 7A corresponding to plan A-A and plan B-B.

The jogs of the active regions 104N may overlap (over are directly under) the gate stacks 136 of the pull-down transistors PD-1 and PD-2, and the jogs of the active regions 104P may overlap (over are directly under) the gate stacks 136 of the pull-up transistors PU-1 and PU-2, as shown in FIG. 7A, in accordance with some embodiments. The lower fin elements 103 of the active regions 104N and 104P have sharp jogs, and have substantially the same profile as the active regions 104N and 104P of the layout shown in FIG. 7A, as shown in FIG. 7B-1, in accordance with some embodiments.

In some embodiments, the nanostructures 108 of the pull-down transistors PD-1 and PD-2 have jogs on the side facing the pull-up transistors PU-1 and PU-2, as shown in FIG. 7B-2. The nanostructures 108 of the pull-down transistors PD-1 and PD-2 include narrower portions with the dimension D1 and wider portions with the dimension D2, in accordance with some embodiments. Correspondingly, the nanostructures 108 of the pull-up transistors PU-1 and PU-2 have jogs on the opposite sides.

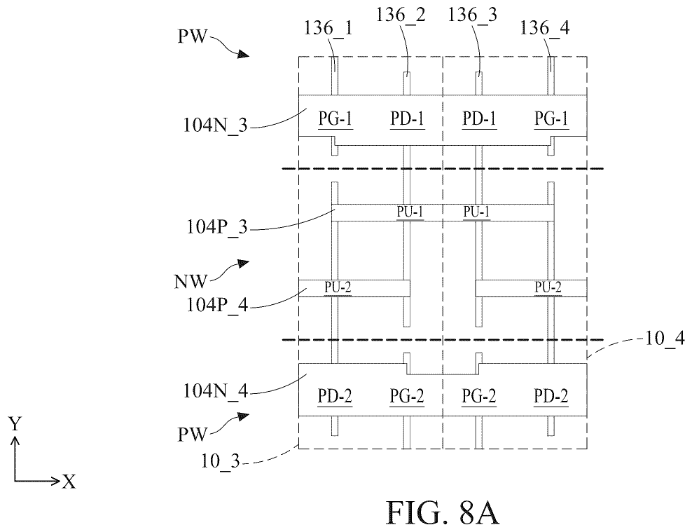

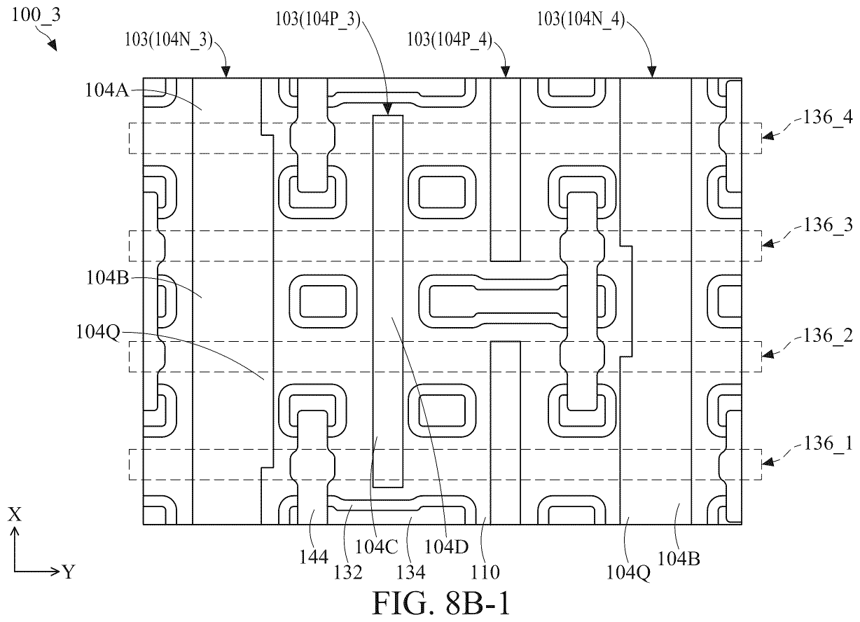

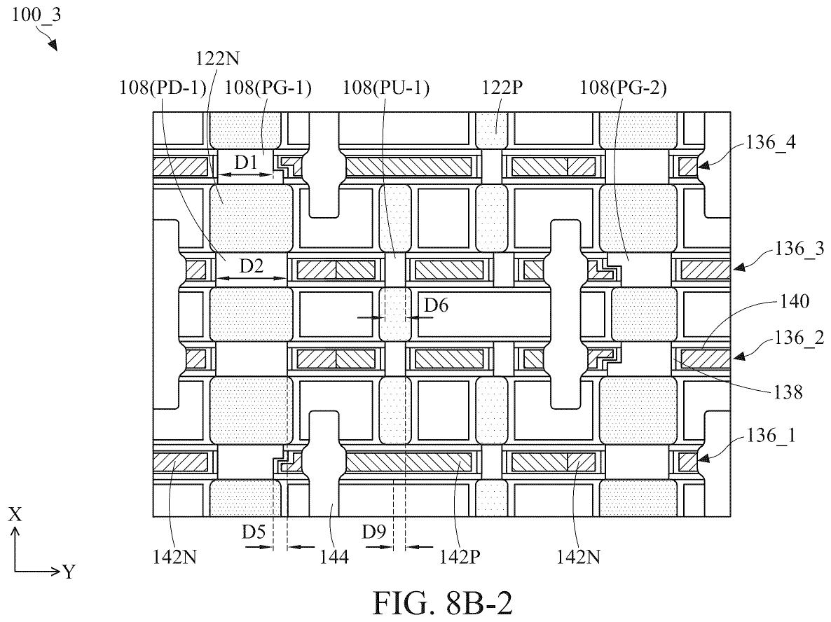

FIG. 8A illustrates a layout showing half of a group GP of the SRAM in FIG. 2 in accordance with some embodiments of the disclosure. FIGS. 8B-1 and 8B-2 are plan views of a semiconductor structure 100_3 of the SRAM cells of FIG. 8A corresponding to plan A-A and plan B-B.

The jogs of the active regions 104N may overlap (over are directly under) the gate stacks 136 of the pass-gate transistors PG-1 and PG-2, and the active regions 104P have no jogs, as shown in FIG. 8A, in accordance with some embodiments. The lower fin elements 103 of the active regions 104N have sharp jogs, and have substantially the same profile as the active regions 104N of the layout shown in FIG. 8A, as shown in FIG. 8B-1, in accordance with some embodiments.

In some embodiments, the nanostructures 108 of the pass-gate transistors PG-1 and PG-2 have jogs on the side facing the pull-up transistors PU-1 and PU-2, as shown in FIG. 8B-2. The nanostructures 108 of the pass-gate transistors PG-1 and PG-2 include narrower portions with the dimension D1 and wider portions with the dimension D2, as shown in FIG. 7B-2, in accordance with some embodiments.

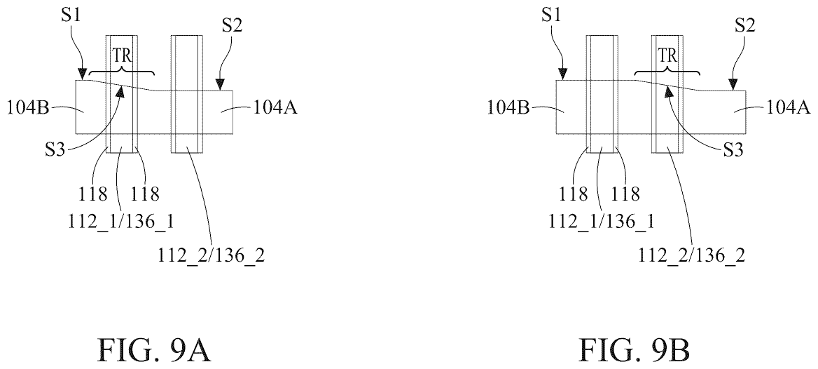

FIG. 9A is a plan view illustrating an active region, in accordance with some embodiments of the disclosure. The embodiments of FIG. 9A are similar to the embodiments of FIGS. 7A to 7B-2, except that the active region 104N has a smooth jog. The transition zones TR of the active region 104N overlap (over are directly under) the gate stacks 136 (or the dummy gate structure 112) of the pull-down transistors PD-1 and PD-2, as shown in FIG. 9A, in accordance with some embodiments.

FIG. 9B is a plan view illustrating an active region, in accordance with some embodiments of the disclosure. The embodiments of FIG. 9B are similar to the embodiments of FIGS. 8A to 8B-2, except that the active region 104N has a smooth jog. The transition zones TR of the active region 104N overlap (over are directly under) the gate stacks 136 (or the dummy gate structure 112) of the pass-gate transistors PG-1 and PG-2, as shown in FIG. 9B, in accordance with some embodiments.

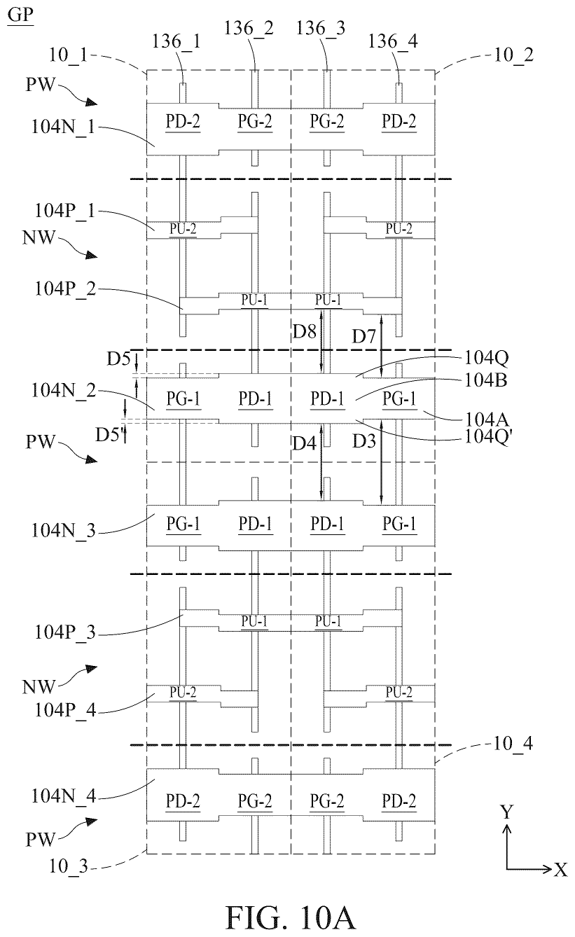

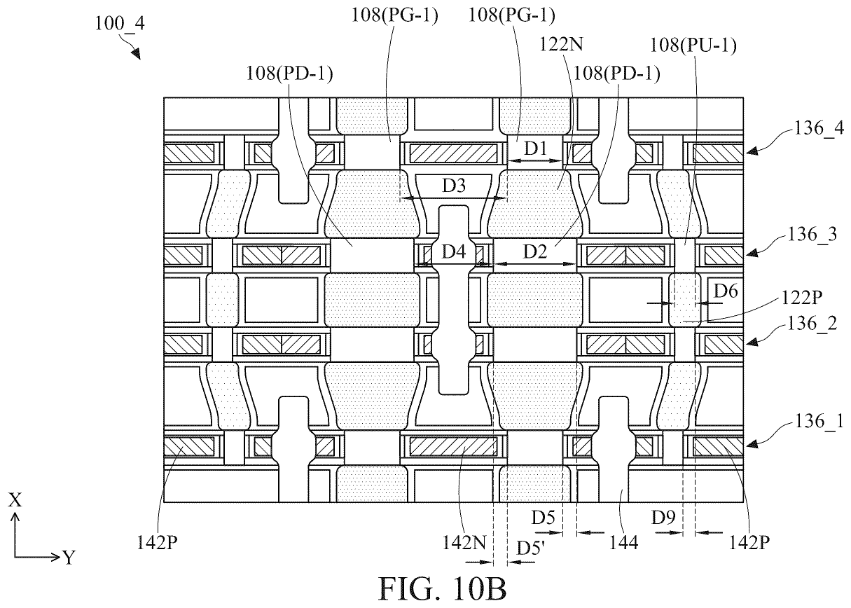

FIG. 10A illustrates a layout showing a group GP of the SRAM in FIG. 2, in accordance with some embodiments of the disclosure. FIG. 10B is a plan view of a semiconductor structure 100_4 of the SRAM cells of FIG. 10A corresponding to plan B-B. The embodiments of FIGS. 10A and 10B are similar to the embodiments of FIGS. 4A to 4G-3, except that the active regions 104N have protrusions on the opposite sides.

In some embodiments where the risk of merging between the N-type source/drain features of the neighboring pull-down transistors PD-1 and PD-2 is relatively low, each of the active regions 104N includes protruding portions 104Q and 104Q′, as shown in FIG. 10A, in accordance with some embodiments. The protruding portion 104Q extends the distance D5 in the Y direction toward a neighboring active region 104P, and the protruding portion 104Q′ a distance D5′ extends in the Y direction toward a neighboring active region 104N, in accordance with some embodiments. In some embodiments, the distance D5′ is substantially equal to the distance D5.

In some embodiments, the distance D3 between the narrower portions 104A of neighboring active regions 104N is greater as the distance D4 between the wider portions 104B of neighboring active regions 104N, as shown in FIG. 10A.

In some embodiments, the distance D7 between the narrower portion 104A of the active region 104N and the first portion 104C of the active region 104P is substantially equal to the distance D8 between the wider portion 104B of the active region 104N and the second portion 104D of the active region 104P.

The lower fin elements 103 of the active regions 104N and 104P may have substantially the same profile as the active regions 104N and 104P of the layout shown in FIG. 10A, in accordance with some embodiments. In some other embodiments, the lower fin elements 103 of the active regions 104N and 104P may be formed with smooth jogs as described above.

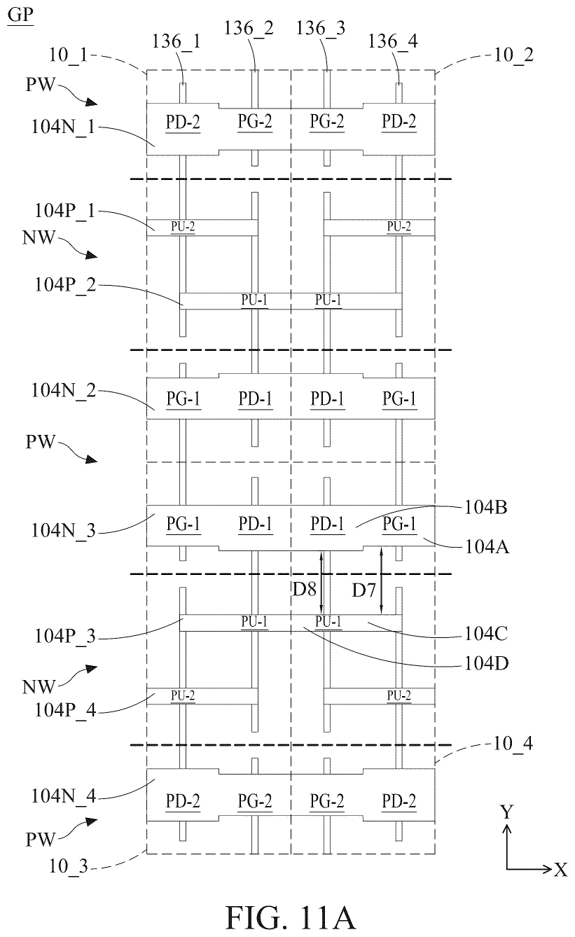

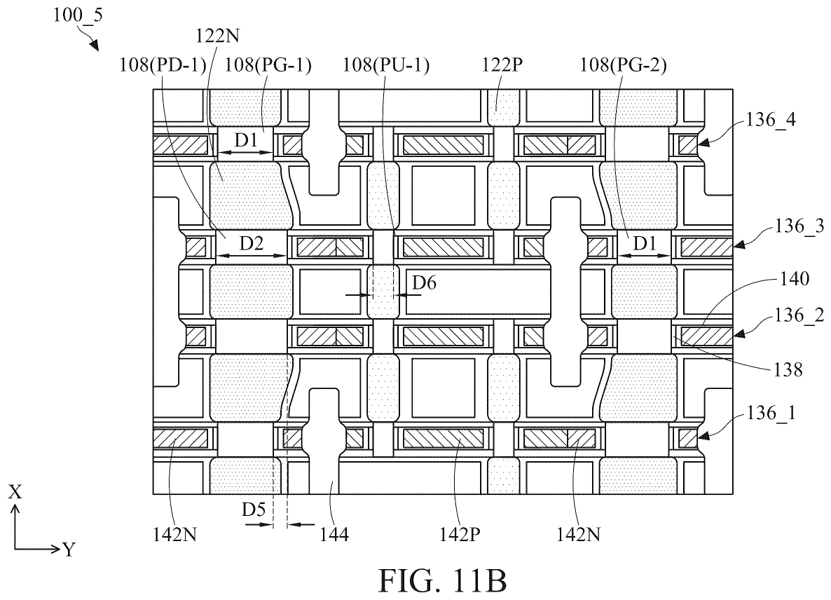

FIG. 11A illustrates a layout showing a group GP of the SRAM in FIG. 2, in accordance with some embodiments of the disclosure. FIG. 11B is a plan view of a semiconductor structure 100_5 of the SRAM cells of FIG. 11A corresponding to plan B-B. The embodiments of FIGS. 11A and 11B are similar to the embodiments of FIGS. 4A to 4G-3, except that the active regions 104P has no jogs.

In some embodiments where the risk of merging between the N-type source/drain feature of the pull-down transistors PD-1 or PD-2 and the P-type source/drain feature of the neighboring pull-up transistors PU-1 or PU-2 is relatively low, the active regions 104P are semiconductor strips without jogs. In some embodiments, the distance D7 between the narrower portion 104A of the active region 104N and the first portion 104C of the active region 104P is greater than the distance D8 between the wider portion 104B of the active region 104N and the second portion 104D of the active region 104P.

The lower fin elements 103 of the active regions 104N and 104P may have substantially the same profile as the active regions 104N and 104P of the layout shown in FIG. 11A, in accordance with some embodiments. In some other embodiments, the lower fin elements 103 of the active regions 104N may be formed with smooth jogs as described above.

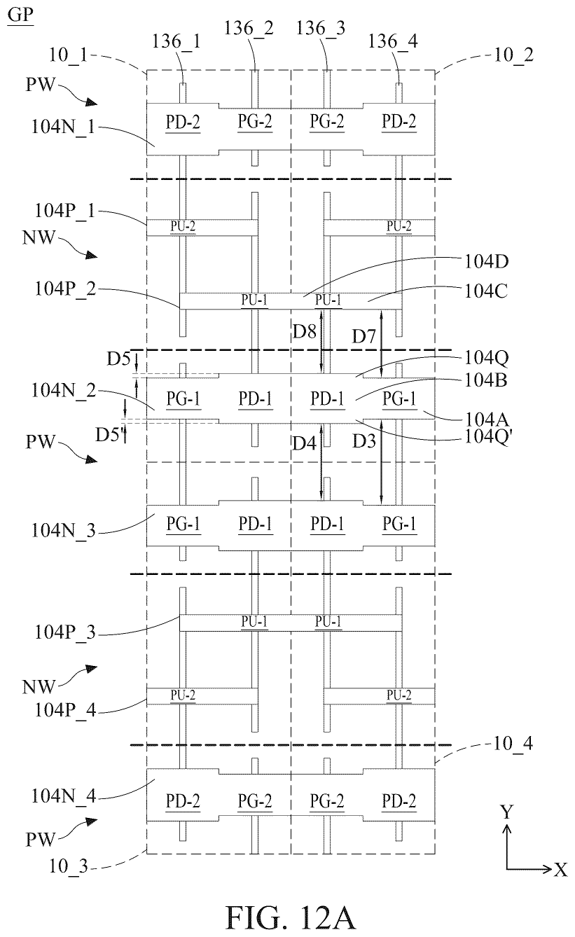

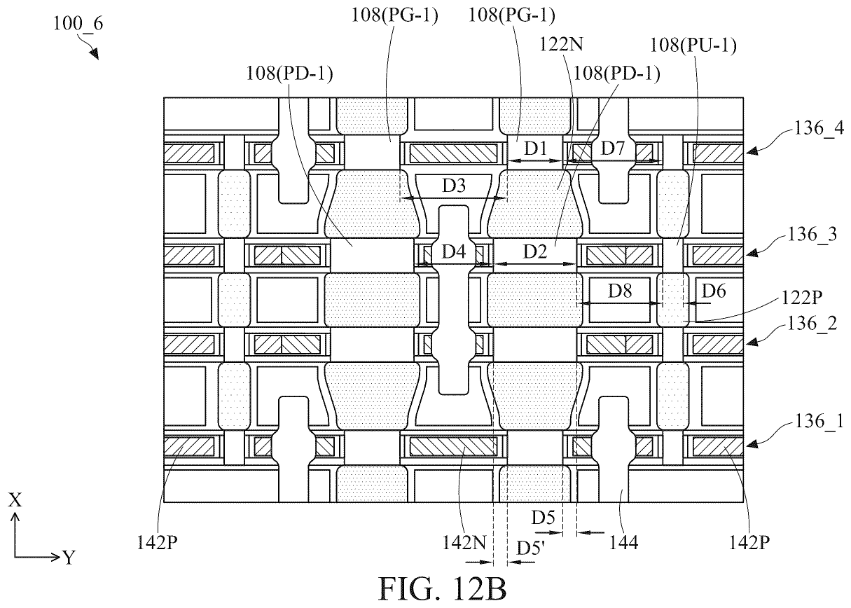

FIG. 12A illustrates a layout showing a group GP of the SRAM in FIG. 2, in accordance with some embodiments of the disclosure. FIG. 12B is a plan view of a semiconductor structure 100_6 of the SRAM cells of FIG. 12A corresponding to plan B-B, in accordance with some embodiments of the disclosure. The embodiments of FIGS. 12A and 12B are similar to the embodiments of FIGS. 10A and 10B, except that the active regions 104P has no jogs.

In some embodiments where the risk of merging between the source/drain features is relatively low, the distance D3 between the narrower portions 104A of neighboring active regions 104N is greater as the distance D4 between the wider portions 104B of neighboring active regions 104N, and the distance D7 between the narrower portion 104A of the active region 104N and the first portion 104C of the active region 104P is greater than the distance D8 between the wider portion 104B of the active region 104N and the second portion 104D of the active region 104P.

The lower fin elements 103 of the active regions 104N and 104P may have substantially the same profile as the active regions 104N and 104P of the layout shown in FIG. 12A, in accordance with some embodiments. In some other embodiments, the lower fin elements 103 of the active regions 104N may be formed with smooth jogs as described above.

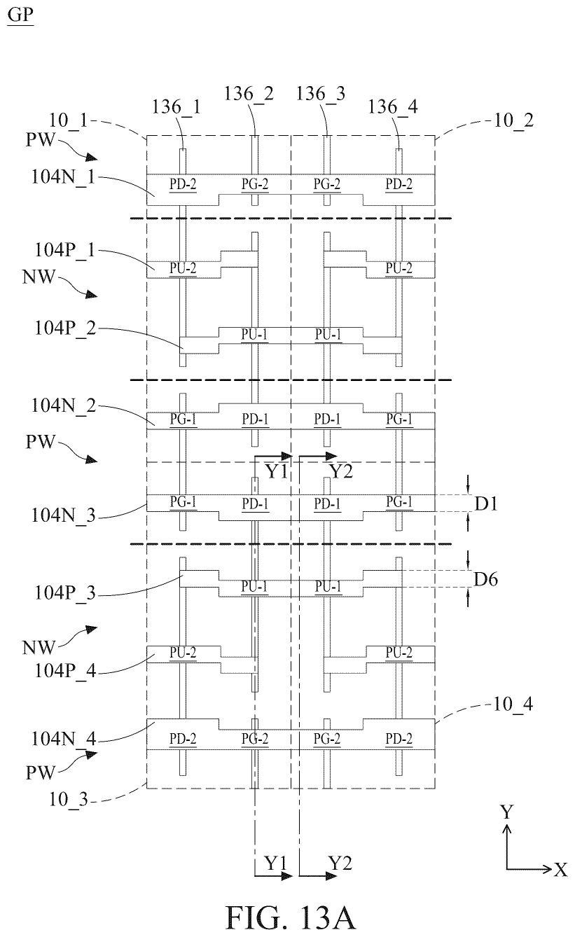

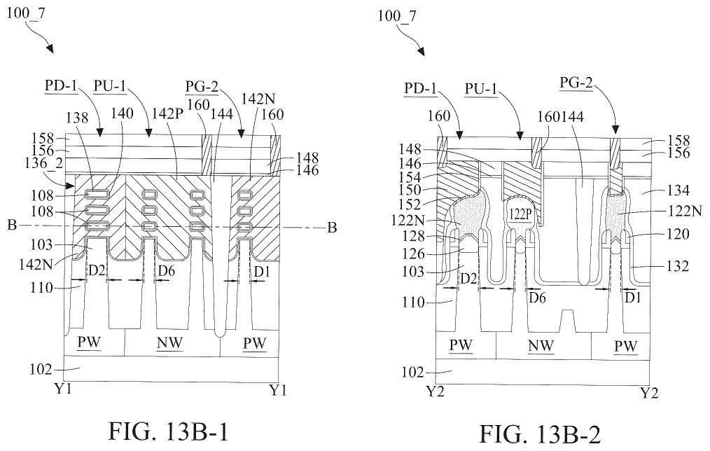

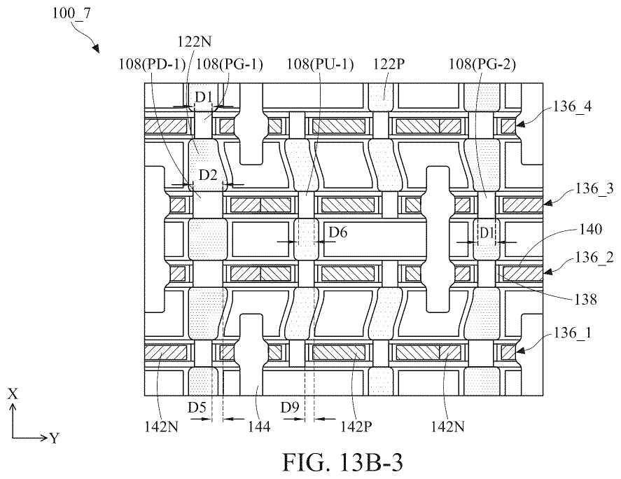

FIG. 13A illustrates a layout showing a group GP of the SRAM in FIG. 2, in accordance with some embodiments of the disclosure. FIGS. 13B-1 and 13B-2 are cross-sectional views of a semiconductor structure 100_7 of an SRAM cell corresponding to line Y1-Y1 and line Y2-Y2 of FIG. 13A. FIG. 13B-3 is a plan view corresponding to plan B-B of FIG. 13B-1. The embodiments of FIGS. 13A to 13B-3 are similar to the embodiments of FIGS. 4A to 4G-3, except that the semiconductor structure 100_7 may be used for SRAM with a high-density design.

In some embodiments, the dimension D6 of the active regions 104P (or the nanostructures 108 of the pull-up transistors PU-1 and PU-2) is substantially equal to the dimension D1 of the narrower portions 104A of the active regions 104N (or the nanostructures 108 of the pass-gate transistors PG-1 and PG-2).

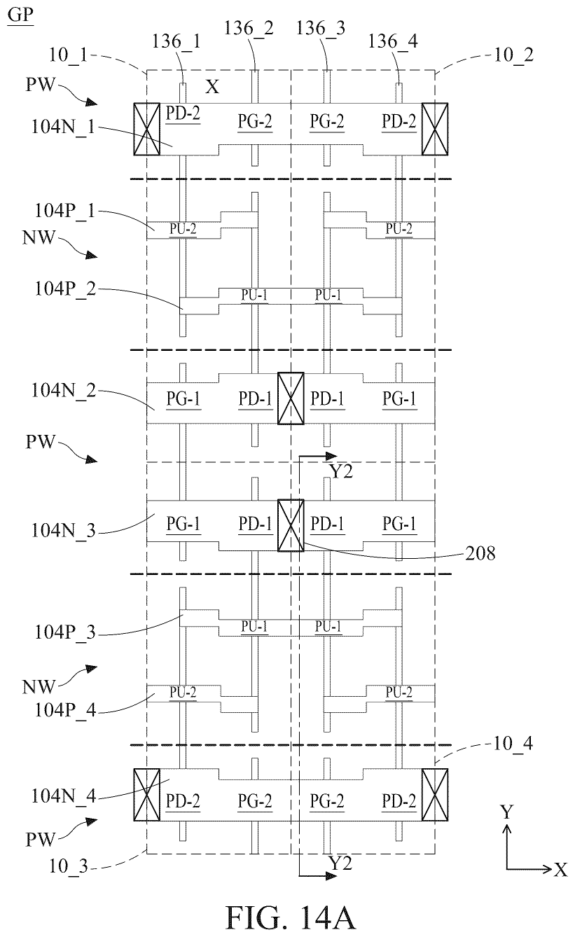

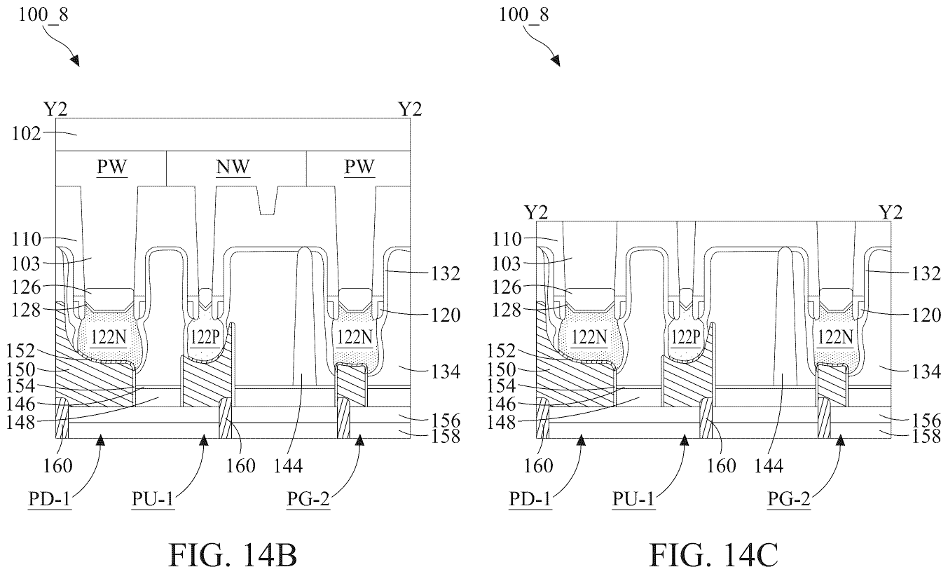

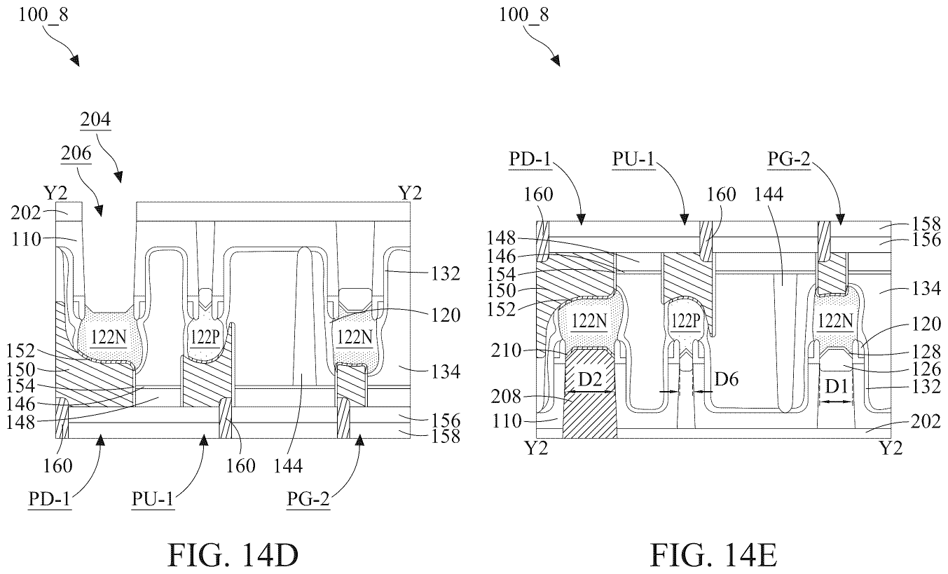

FIG. 14A illustrates the configuration of backside contact plugs 208 on the layout of FIG. 4A, in accordance with some embodiments of the disclosure.

The source terminals of the pull-down transistor PD-1 and the pull-down transistor PD-2 are electrically connected to a backside VSS power rail through backside contact plugs 208, in accordance with some embodiments. Backside power rails may reduce the overall resistance of the BEOL (backend of lines) metal layers, and/or the complexity of the metal routing on the frontside of the substrate.

FIGS. 14B-14E are cross-sectional views illustrating the formation of a semiconductor structure 100_8 of an SRAM cell at various intermediate stages corresponding to line Y2-Y2 of FIG. 14A, in accordance with some embodiments of the disclosure.

FIG. 14B illustrates a semiconductor structure 100_8 after flipping the semiconductor structure 100_8, in accordance with some embodiments.

The semiconductor structure 100_8 is flipped upside down, as shown FIG. 14B, in accordance with some embodiments. In some embodiments, a carrier substrate (not shown) may be formed over and seal the frontside of the semiconductor structure 100_8 before flipping the semiconductor structure 100_8 to protect of components of the semiconductor structure 100 during subsequent backside processes. After flipping the semiconductor structure 100_8, the backside surface of the substrate 102 (the backside of the semiconductor structure 100_8) faces upward, in accordance with some embodiments.

FIG. 14C illustrates a semiconductor structure 100_8 after a removal process, in accordance with some embodiments.

The substrate 102 and the well regions PW and NW are removed from the backside of the semiconductor structure 100_8 using a planarization process such as CMP, an etching process, or a combination thereof until the isolation structure 110 is exposed, as shown in FIG. 14C, in accordance with some embodiments. In some embodiments, the lower fin elements 103 may be also thinned down in the removal process.

FIG. 14D illustrates a semiconductor structure 100_8 after the formation of a contact opening 206, in accordance with some embodiments.

A patterning process is performed on the lower fin element 103 to form a contact opening 206 using photolithography and etching processes, as shown in FIG. 14D, in accordance with some embodiments. The patterning process includes forming a mask layer 202 over the backside of the semiconductor structure 100_8, in accordance with some embodiments. The mask layer 202 has an opening 204 corresponding to the source/drain feature 122N of the pull-down transistor PD-1, in accordance with some embodiments.

The mask layer 202 may be made of silicon nitride, silicon oxide, carbon-doped silicon dioxide (e.g., SiO₂:C), metal oxide (e.g., AlO, TiO, LaO, HfO, etc.), a nitrogen-free anti-reflection layer (NFARL), titanium nitride (TiN), boron nitride (BN), a multilayer thereof, another suitable material, or a combination thereof. For example, the mask layer 202 is deposited over the backside of the semiconductor structure 100_8, and a photoresist is then formed on the material for the mask layer 202 such as by using spin-on coating, and patterned by exposing the photoresist to light using an appropriate photomask. Exposed or unexposed portions of the photoresist may be removed depending on whether a positive or negative resist is used. The material for the mask layer 202 may be etched using the patterned photoresist layer to form the opening 204.

The patterning process also includes performing an etching process using the mask layer 202 to remove the lower fin element 103, the semiconductor isolation features 126, and dielectric isolation features 128, thereby forming the contact opening 206 exposing the source/drain feature 122N, in accordance with some embodiments. The etch process may include dry etching such as RIE, NBE, ICP etch, CCP etch, another suitable method, or a combination thereof.

FIG. 14E illustrates a semiconductor structure 100_8 after the formation of a backside contact plug 208, in accordance with some embodiments. It should be noted that the semiconductor structure 100 in FIG. 14E is illustrated with its frontside facing upward.

A silicide layer 210 is formed on the backside surface of the source/drain feature 122N exposed from the contact opening 206, as shown in FIG. 14E, in accordance with some embodiments. In some embodiments, the silicide layer 210 are made of WSi, NiSi, TiSi and/or CoSi. In some embodiments, the formation of the silicide layer 210 includes depositing a metal material followed by one or more annealing processes. The semiconductive material (e.g., Si) from the source/drain feature 122N reacts with the metal material to form the silicide layer 210, in accordance with some embodiments.

Backside contact plug 208 is then formed on the silicide layer 210 in the contact opening 206, as shown in FIG. 14E, in accordance with some embodiments. The contact plug 208 is electrically connected to a subsequently formed backside VSS power supply line, in accordance with some embodiments. In some embodiments, the backside contact plug 208 has the dimension D2 in the Y direction, which is greater than the dimension D1 of the lower fin element 103 directly below the pass-gate transistor PG-1 (i.e., the narrower portion 104A of the active region 104N).

In some embodiments, the formation of the contact plug 208 includes depositing one or more conductive materials for the contact plug 208 to overfill the contact opening 206, in accordance with some embodiments. In some embodiments, one or more conductive materials are deposited using CVD, PVD, e-beam evaporation, ALD, ECP, ELD, another suitable method, or a combination thereof to overfill the contact opening 206. The one or more conductive materials are planarized using, for example, CMP until the mask layer 202 is exposed.

The contact plug 208 may have a multilayer structure. For example, a barrier/adhesive layer (not shown) may optionally be deposited along the sidewalls and the bottom surfaces of the contact opening 206. The barrier layer may be made of Ta, TaN, Ti, TiN, CoW, another suitable material, or a combination thereof. A metal bulk layer is then deposited on the barrier/adhesive layer (if formed) to fill the remainder of the contact opening 206. In some embodiments, the metal bulk layers are made of one or more conductive materials, such as Co, Ni, W, Ti, Ta, Cu, Rh, Ir, Pt, Al, Ru, Mo, or a combination thereof.

The semiconductor structure 100_8 may undergo further backside BEOL processes to form various interconnection conductive features (not shown) over the backside of the semiconductor structure 100, such as backside metal layers, vias between neighboring two metal layers, passivation layers, bump pads, etc.

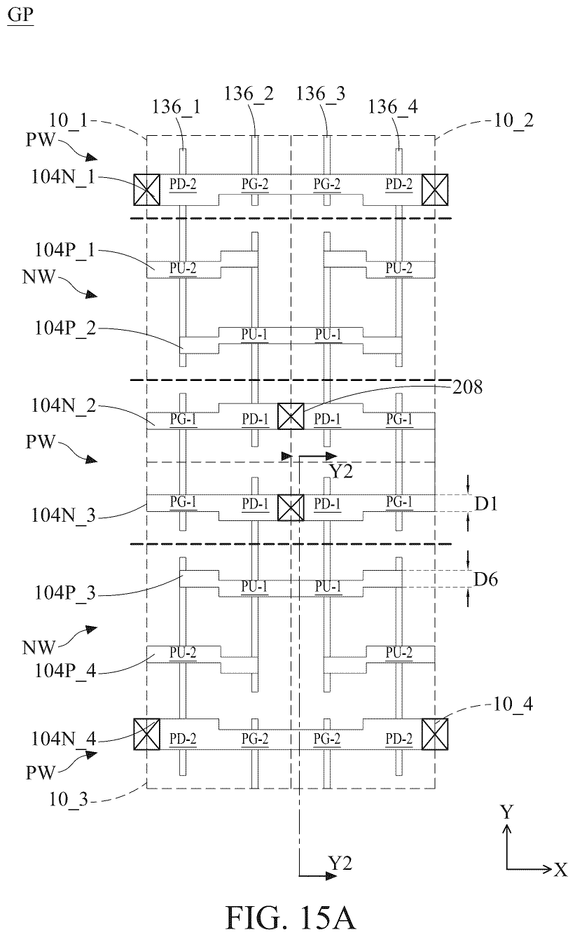

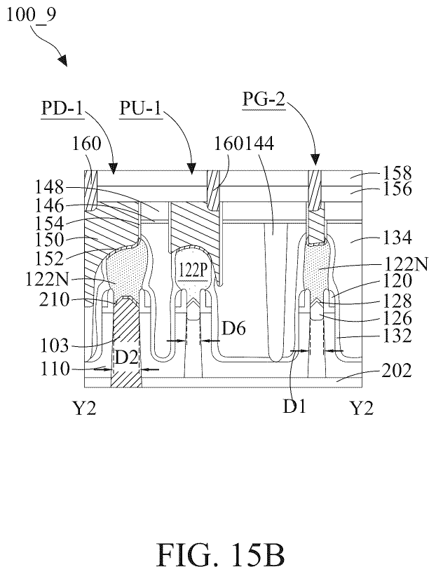

FIG. 15A illustrates the configuration of backside contact plugs 208 on the layout of FIG. 13A, in accordance with some embodiments of the disclosure. FIG. 15B is a cross-sectional view of a semiconductor structure 100_9 of an SRAM cell corresponding to line Y2-Y2 of FIG. 15A.

In some embodiments, the semiconductor structure 100_9 may be used for SRAM with a high-density design. The source terminals of the pull-down transistor PD-1 and the pull-down transistor PD-2 are electrically connected to a backside VSS power rail through backside contact plugs 208, as shown in FIG. 15A, in accordance with some embodiments. The material and the formation of the backside contact plugs 208 are the same as or similar to the material and the formation of the backside contact plugs 208 described above in FIGS. 14B-14E, in accordance with some embodiments.

Compared with SRAM with a high-current design, the active regions of the SRAM with a high-density design are relatively narrow, and thus the processing of forming the backside contact plugs is more difficult. In the embodiments of the present disclosure, the active regions 104N include the wider portions 104B on which the pull-down transistors are formed, which may reduce the processing difficulty of forming the backside contact plugs electrically connected to the VSS power rail.

The lower fin elements 103 of the active regions 104N and 104P may have substantially the same profile as the active regions 104N and 104P of the layout shown in FIG. 15A, in accordance with some embodiments. In some other embodiments, the lower fin elements 103 of the active regions 104P may be formed with smooth jogs as described above.

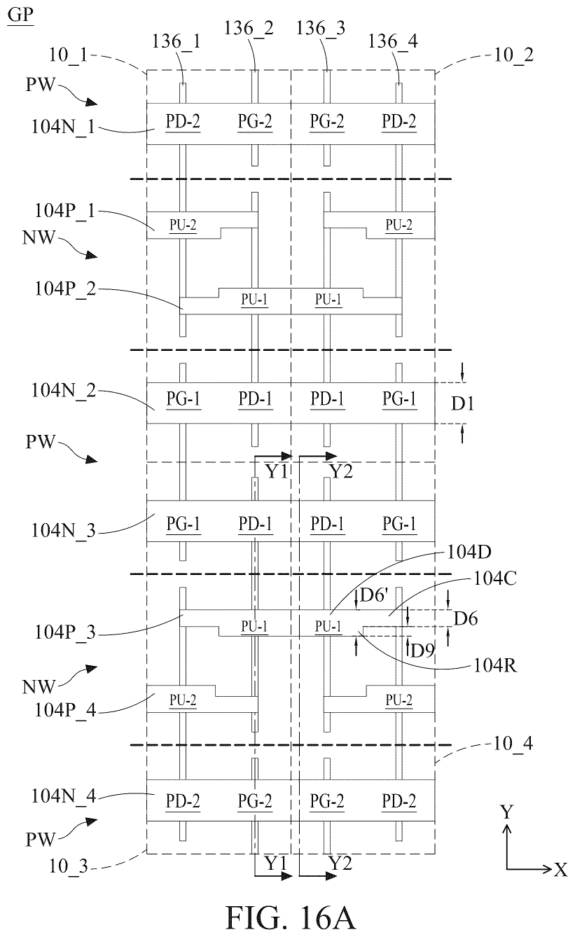

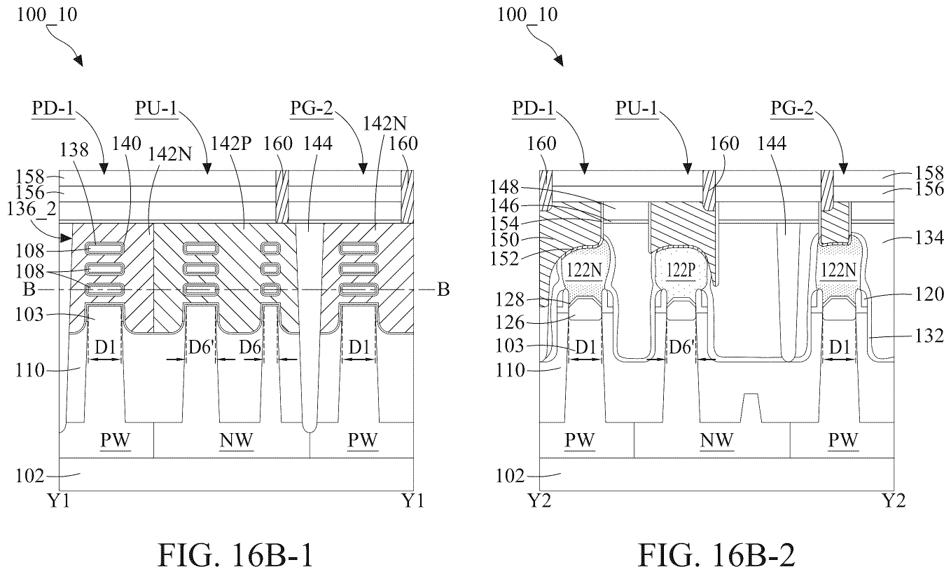

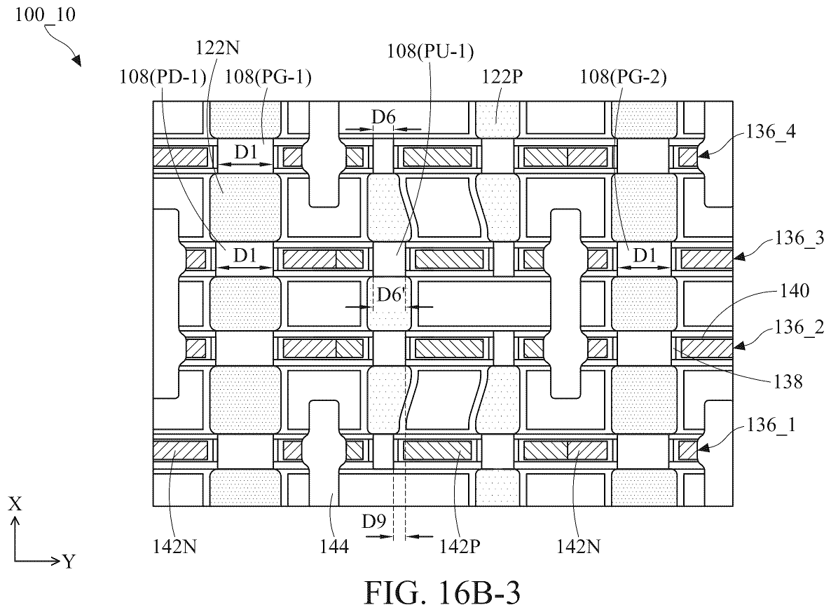

FIG. 16A illustrates a layout showing a group GP of the SRAM in FIG. 2, in accordance with some embodiments of the disclosure. FIGS. 16B-1 and 16B-2 are cross-sectional views of a semiconductor structure 100_10 of an SRAM cell corresponding to line Y1-Y1 and line Y2-Y2 of FIG. 16A. FIG. 16B-3 is a plan view corresponding to plan B-B of FIG. 16B-1.

In some embodiments, the SRAM of FIG. 16A has a high-current design. Each of the active regions 104N is a semiconductor strip without jogs, as shown in FIG. 16A, in accordance with some embodiments. In some embodiments, the active regions 104N have the dimension D1 in the Y direction. Each of the active regions 104P is a semiconductor strip with a protruding portion 104R, as shown in FIG. 16A, in accordance with some embodiments. The protruding portion 104R extends a distance D9 in the Y direction toward the neighboring active region 104P, in accordance with some embodiments. That is, each of the active regions 104P includes a narrower first portion 104C and a wider second portion 104D, as shown in FIG. 16A, in accordance with some embodiments. The first portions 104C are dummy regions on which no functional transistors are formed, and the pull-up transistors PU-1 and PU-2 are formed on the wider second portions 104D, in accordance with some embodiments. In some embodiments, the first portions 104C have the dimension D6 in the Y direction. In some embodiments, the second portions 104D have a dimension D6′ that is greater than the dimension D6 and less the dimension D1.

In accordance with some embodiments of the present disclosure, by forming the active regions 104P with jogs, the pull-down transistors PD-1 and PD-2 may have a wider channel width (e.g., the dimension D6′) without increasing the cell height of the SRAM cell. The “alpha ratio” of the saturation current, that is the ratio of PU Idsat to PG Idsat, may thus increase, which may enhance cell performance of the resulting SRAM cells, e.g., increase in higher operation voltage (e.g., Vmax and/or Vmin), higher cell current, broader read margin metric, and/or faster operation speed.

In some embodiments, the distance D9 is in a range from about 2 nm to about 30 nm. The ratio of the distance D9 to the gate length in a range from about 2 to about 5. The dimension D6 is in a range from about 6 nm to about 35 nm. The ratio of the dimension D6 to the gate length in a range from about 0.6 to about 2. In some embodiments, the dimension D6′ is in a range from about 6 nm to about 35 nm. The ratio of the dimension D6′ to the gate length in a range from about 0.6 to about 2.

In some embodiments, the ratio (D6′/D6) of the dimension D6′ to the dimension D6 is in range from about 1.02 to about 2. If the ratio is too small (e.g., smaller than 1.02), the alpha ratio may increase too little, and the cell performance of the resulting SRAM may not significantly increase. If the ratio is too large (e.g., greater than 2), the jog transition may be too long, such that the active region may have an undesirable profile.

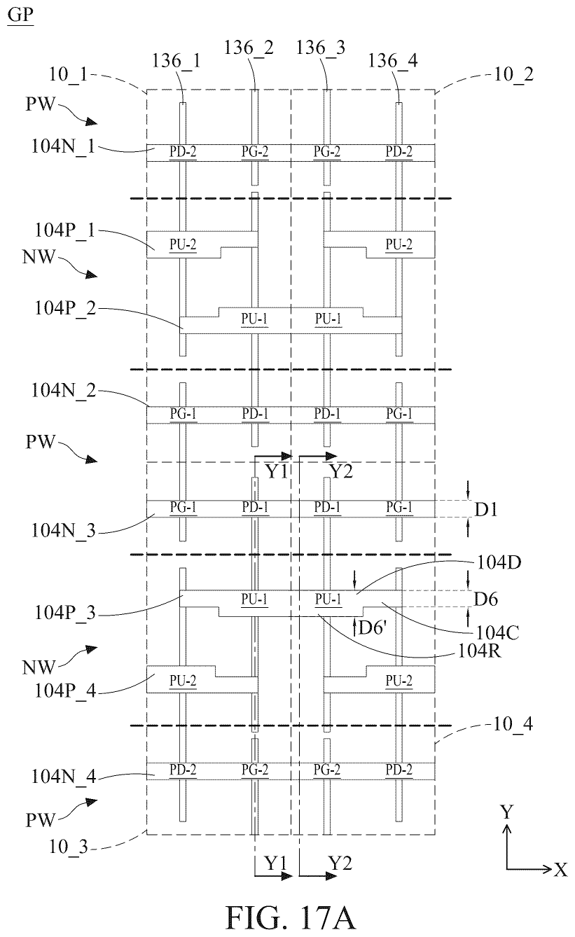

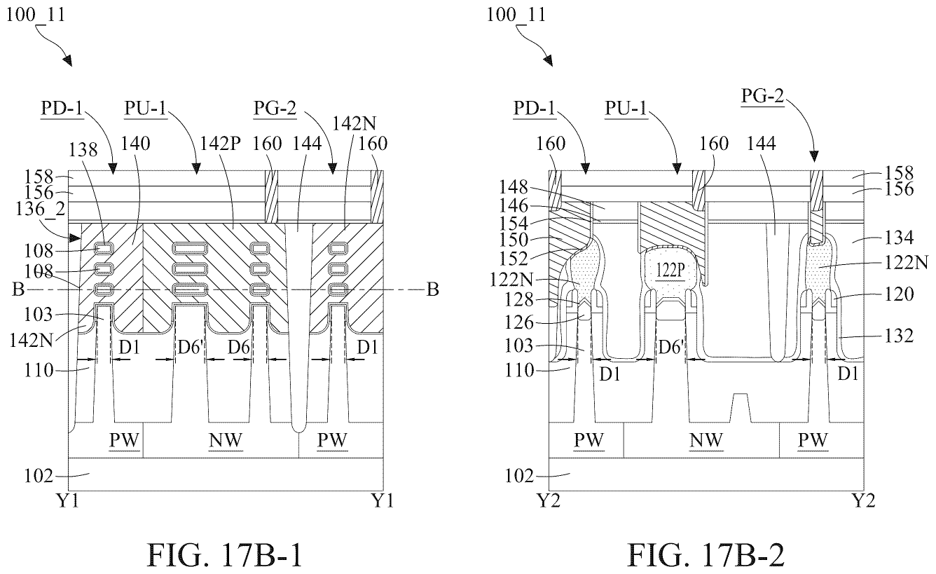

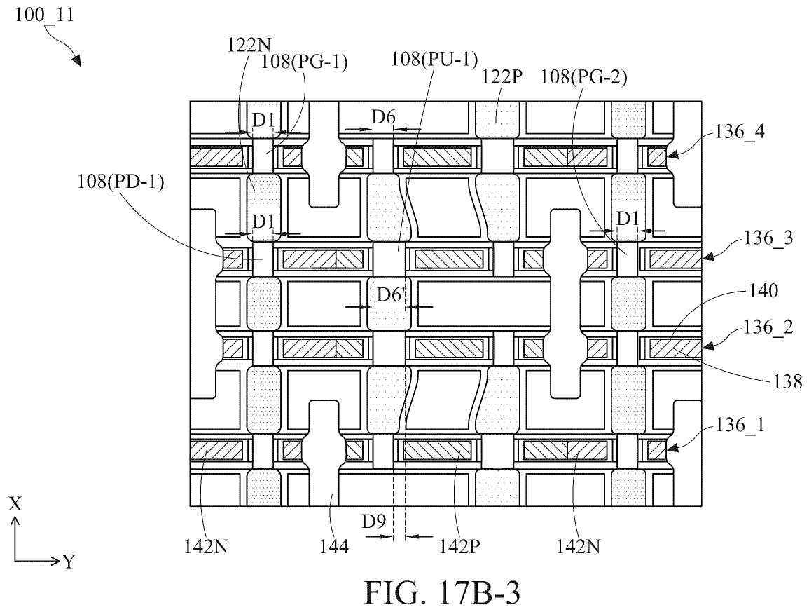

FIG. 17A illustrates a layout showing a group GP of the SRAM in FIG. 2, in accordance with some embodiments of the disclosure. FIGS. 17B-1 and 17B-2 are cross-sectional views of a semiconductor structure 100_11 of an SRAM cell corresponding to line Y1-Y1 and line Y2-Y2 of FIG. 17A. FIG. 17B-3 is a plan view corresponding to plan B-B of FIG. 17B-1. The embodiments of FIGS. 17A to 17B-3 are similar to the embodiments of FIGS. 16A to 16B-3, except that the semiconductor structure 100_11 may be used for SRAM with a high-density design.

In some embodiments, the dimension D6 of the first portions 104C of the active regions 104P is substantially equal to the dimension D1 of the narrower portions 104A of the active region 104N (or the nanostructures 108 of the pass-gate transistors PG-1 and

PG-2 and the pull-down transistors PD-1 and PD-2). In some embodiments, the dimension D6′ of the second portions 104D of the active regions 104P (or the nanostructures 108 of the pull-up transistors PU-1 and PU-2) is greater than the dimension D1.

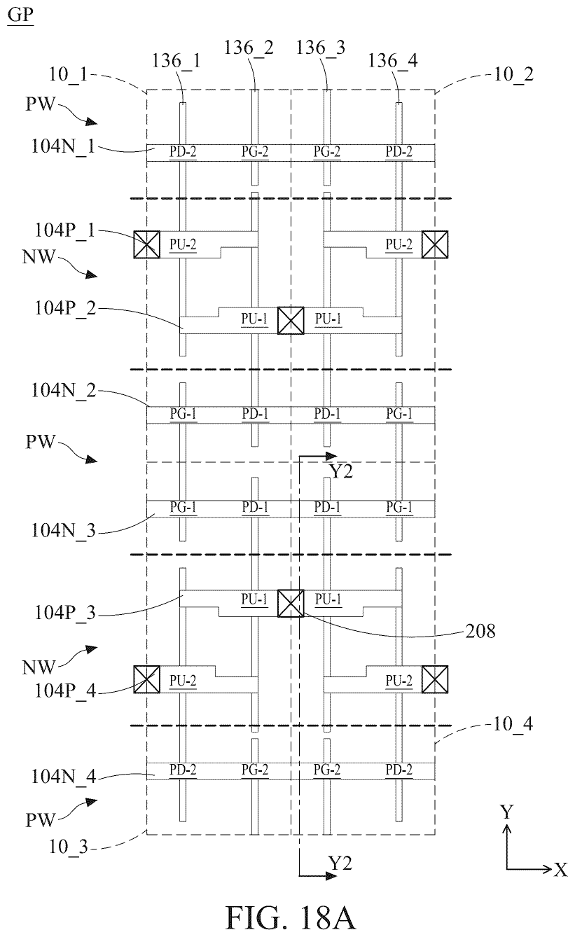

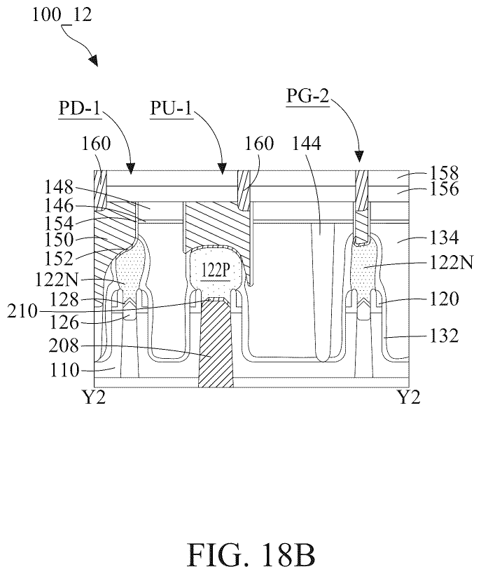

FIG. 18A illustrates the configuration of backside contact plugs 208 on the layout of FIG. 17A, in accordance with some embodiments of the disclosure. FIG. 18B is a cross-sectional view of a semiconductor structure 100_12 of an SRAM cell corresponding to line Y2-Y2 of FIG. 18A.

In some embodiments, the semiconductor structure 100_12 may be used for SRAM with a high-density design. The source terminals of the pull-up transistor PU-1 and the pull-up transistor PU-2 are electrically connected to a backside VDD power rail through backside contact plugs 208, as shown in FIG. 18A, in accordance with some embodiments. The material and the formation of the backside contact plugs 208 are similar to the material and the formation of the backside contact plugs 208 described above in FIGS. 14B-14E, in accordance with some embodiments.

Compared with SRAM with a high-current design, the active regions of the SRAM with a high-density design are relatively narrow, and thus the processing of forming the backside contact plugs is more difficult. In the embodiments of the present disclosure, the active regions 104P includes the wider second portions 104D on which the pull-up transistors are formed, which may reduce the processing difficulty of forming the backside contact plugs electrically connected to the VDD power rail.

As described above, the aspect of the present disclosure is directed to forming a semiconductor structure of an SRAM device including nanostructure transistors. The active regions 104N may have jog, and thus independent adjustment of the performances of the pull-down transistors PD-1/PD-2 and the pass-gate transistors PG-1/PG-2 may be achieved. Because the channel width of the pull-down transistors PD-1/PD-2 is greater than the channel width of the pass-gate transistors PG-1/PG-2, the beta ratio of the saturation current may increase, which may enhance the cell performance of the resulting SRAM cells, e.g., higher operation voltage (e.g., Vmax), higher cell current, broader read margin metric, and/or faster operation speed.

Embodiments of a semiconductor structure and the method for forming the same may be provided. The method for forming a semiconductor structure may include forming an active region. A first portion of the active region may be wider than a second portion of the active region. As a result, the pull-down transistor formed on the first portion of the active region may have a stronger performance than the pass-gate transistor formed on the second portion of the active region. Therefore, the cell performance of the resulting SRAM cells may be improved.

In some embodiments, a method for forming a semiconductor structure is provided. The method includes forming a first active region in which first semiconductor layers and second semiconductor layers are alternatingly stacked over a first lower fin element. In a plan view, the active region includes a first portion and a second portion. The second portion is narrower than the first portion. The method also includes removing the first semiconductor layers of the first active region. The second semiconductor layers of the first portion of the first active region form a plurality of first nanostructures, and the second semiconductor layers of the second portion of the first active region form a plurality of second nanostructures. The method also includes forming a first gate stack to surround the first nanostructures, and forming a second gate stack to surround the second nanostructures.

In some embodiments, a method for forming a semiconductor structure is provided. The method includes alternatively stacking sacrificial layers and channel layers over a substrate, and patterning the sacrificial layers, the channel layers and the substrate to form a first fin structure in a p-type well of the substrate and a second fin structure in an n-type well of the substrate. The first fin structure includes a strip portion and a first protruding portion extending toward the second fin structure. The method also includes forming a dummy gate structure across the first fin structure and the second fin structure. The dummy gate structure overlaps the first protruding portion of the first fin structure.

In some embodiments, a semiconductor structure is provided. The semiconductor structure includes a first pull-down transistor of a first static random access memory cell and a pass-gate transistor of the first static random access memory cell. The first pull-down transistor includes a plurality of first nanostructures, and a first gate stack surrounding the first nanostructures and extending in a first direction. The pass-gate transistor includes a plurality of second nanostructures, and a second gate stack surrounding the second nanostructures and extending in the first direction. The plurality of first nanostructures has a first dimension in the first direction, the plurality of second nanostructures has a second dimension in the first direction, and the first dimension is greater than the second dimension.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first active region having a first vertical stack of semiconductor layers, the first active region extending in a first direction in a top view;
a second active region having a second vertical stack of semiconductor layers, the second active region extending in the first direction in the top view;
an isolation region extending between the first active region and the second active region in a second direction in the top view; and
a gate stack extending in the second direction and over the first active region and the second active region;
wherein the first active region includes a first width in the second direction in the top view under the gate stack and a second width in the second direction at a region spaced a distance in the second direction from the gate stack;
wherein the second active region includes a third width in the second direction under the gate stack, wherein the first width is greater than the second width and the third width.

2. The semiconductor structure of claim 1, wherein the gate stack surrounds the first vertical stack of semiconductor layers to form a pull-down transistor of a static random access memory cell.

3. The semiconductor structure of claim 2, wherein the gate stack surrounds the second vertical stack of semiconductor layers to form a pull-up transistor of the static random access memory cell.

4. The semiconductor structure of claim 1, wherein another gate stack surrounds the first vertical stack of semiconductor layers having the second width at the region spaced the distance in the second direction from the gate stack.

5. The semiconductor structure of claim 4, wherein the another gate stack forms a pass-gate transistor of a static random access memory cell.

6. The semiconductor structure of claim 1, further comprising:
a contact disposed over the first active region at a transition between the first width and the second width.

7. The semiconductor structure of claim 1, wherein a first separation distance in the second direction in the top view is between the first active region having the first width and the second active region; and wherein a second separation distance in the second direction in the top view is between the first active region having the second width and the second active region, wherein the first separation distance and the second separation distance are approximately equal.

8. The semiconductor structure of claim 1, wherein the second active region has a jog in the top view.

9. The semiconductor structure of claim 8, wherein the jog has a jog distance in the second direction of the top view, and wherein a ratio of the first distance minus the second distance to the jog distance is equal to or greater than one.

10. A semiconductor structure, comprising:
an active region extending in a first direction in a top view, wherein the active region includes:
a first portion having a first width in a second direction in the top view;
a second portion having a second width in the second direction in the top view, wherein the second width is different than the first width;
a transition portion between the first portion and the second portion, the transition portion changes from the first width to the second width;
a first gate structure over the first portion; and
a second gate structure over the second portion, wherein the second gate structure is a next adjacent gate structure to the first gate structure.

11. The semiconductor structure of claim 10, wherein the transition portion has a curved or a straight line sidewall that extends in the first direction from the first width to the second width.

12. The semiconductor structure of claim 10, wherein the transition portion is disposed between a first gate spacer on the first gate structure and a second gate spacer on the second gate structure.

13. The semiconductor structure of claim 12, wherein the transition portion does not extend below the first gate spacer or the second gate spacer.

14. The semiconductor structure of claim 10, wherein the active region for forming n-type devices.

15. The semiconductor structure of claim 10, wherein the transition portion has a straight line sidewall that extends in the second direction from the first width to the second width.

16. The semiconductor structure of claim 10, wherein the first gate structure and the active region form a pull-down transistor and the second gate structure and the active region provide a pass-gate transistor.

17. A semiconductor structure, comprising:
a first active region having a first vertical stack of semiconductor layers, the first active region extending in a first direction in a top view;
a second active region having a second vertical stack of semiconductor layers, the second active region extending in the first direction in the top view;
a third active region having a third vertical stack of semiconductor layers, the third active region extending in the first direction in the top view;
a first gate extending in a second direction in the top view, the first gate over the first active region, the second active region, and the third active region;
a second gate extending in the second direction and a next neighboring gate to the first gate in the second direction, the second gate extending over the second active region and the third active region;
wherein the first active region includes a first width in the second direction in the top view under the first gate and a second width at a region collinear in the second direction with the second gate, the second width less than the first width, the first active region having a transition region between the first width and the second width;
wherein the second active region and the third active region each have a width in the second direction in the top view less than the first width and the second width.

18. The semiconductor structure of claim 17, wherein the second active region and the third active region each have a jog in a distance between the first gate and the second gate.

19. The semiconductor structure of claim 17, wherein the transition region is aligned with at least one of a jog in the second active region or a jog in the third active region.

20. The semiconductor structure of claim 17, wherein the first gate and the first active region provide a pull-down transistor of a static random access memory (SRAM), the first gate and the second active region form a pull-up transistor of the SRAM, and the second gate and the third active region form another pull-up transistor of the SRAM.
